(19) United States
(12) Patent Application Publication
(10) Pub. No.: US 2019/0317152 A1
(43) Pub. Date: Oct. 17, 2019

(54) REAL-TIME ELECTROCHEMICAL IMPEDANCE SPECTROSCOPY APPARATUS (EISA) TESTING

(71) Applicant: BLOOM ENERGY CORPORATION, San Jose, CA (US)

(72) Inventors: Arne BALLANTINE, Palo Alto, CA (US); John CRONIN, Jericho, VT (US); Joseph BODKIN, Williston, VT (US)

(21) Appl. No.: 16/363,214

(22) Filed: Mar. 25, 2019

Related U.S. Application Data
(60) Provisional application No. 62/647,274, filed on Mar. 23, 2018.

(51) Int. Cl. G01R 31/389; H01M 10/42; H01M 10/44; G01N 27/02; G01R 31/371; H02J 7/00

(52) U.S. Cl. CPC G01R 31/389; H01M 10/4285; H01M 10/44; H02J 7/0047; G01R 31/371; H02J 7/0031; G01N 27/026

(57) ABSTRACT

Electrochemical impedance spectroscopy (EIS) may include testing various voltages and currents, storing and sending the data to an electrochemical impedance spectroscopy analyzer (EISA) network, where the data may be compared to historical data to determine a safety threshold that may provide preferred operating use of a device battery, and in response to a battery level exceeding a safety threshold, the battery may be halted.

### CROSS REFERENCE TO RELATED APPLICATIONS

This application claims the benefit of priority to U.S. Provisional Patent Application Ser. No. 62/647,274 filed Mar. 23, 2018, entitled “Real-Time Electrochemical Impedance Spectroscopy Apparatus (EISA) Testing”, the contents of which are incorporated herein by reference in their entirety.

### BACKGROUND

Batteries may be susceptible to degradation from charging and discharging cycles because of the effects these factors may have on the internal chemistry of batteries. Battery degradation from charge and discharge cycles may be caused by adhesion of oxidized particles to an anode and a cathode reducing a surface area for reacting with an electrolyte, reducing an amount of the electrolyte in the battery, and increase an internal resistance of the battery. Battery degradation may result in a reduced power storage capacity, a reduced voltage output, and an increased self-discharge rate. These degradations of a battery's performance may also reduce a useful life of a battery.

### SUMMARY

The systems, methods, and devices of the various embodiments enable improved charging and safety of batteries based on analysis of electrochemical impedance spectroscopy (EIS) performed on a battery and compared with historical data of EIS testing on batteries. In an embodiment additional EIS testing may be performed on a battery determined to be exhibiting a poor performance event. In an embodiment, results of the EIS testing of the battery experiencing the poor performance event may be analyzed and compared to a threshold. In an embodiment, based on the analysis, a battery protection decision may be made and implemented to protect the battery experiencing the poor performance event. In some embodiments, the implemented decision may cause charging of the battery, notification of a user of a battery powered device electrically connected to the battery via a graphical user interface (GUI) of the battery, and/or halting of the battery operation.

### DESCRIPTION OF THE DRAWINGS

The accompanying drawings, which are incorporated herein and constitute part of this specification, illustrate example embodiments of various embodiments, and together with the general description given above and the detailed description given below, serve to explain the features of the claims.

FIG. 1 is a block diagram illustrating a system according to an embodiment.

FIGS. 2A and 2B are graphs illustrating canceling ripples on a DC bus over time.

FIG. 3 is a process flow diagram illustrating an embodiment method for canceling the ripple to a DC bus caused by a test waveform.

FIG. 4 is a block diagram of a system illustrating injected waveforms and resulting canceling ripples according to an embodiment.

FIG. 5 is a component flow diagram illustrating an example waveform generator for determining an impedance response for a battery.

FIG. 6 is a block diagram of a system according to another embodiment.

FIG. 7 is a block diagram of an electrochemical impedance spectroscopy (EIS) system connected to a device battery, a charger for a battery, a battery powered device, and an electrochemical impedance spectroscopy analyzer (EISA) network according to an embodiment.

FIG. 8 is a process flow diagram illustrating a method for electrochemical impedance spectroscopy (EIS) testing and protection of a battery according to an embodiment.

FIG. 9 is a process flow diagram illustrating a method for making a battery protection recommendation using EIS testing results according to an embodiment.

FIG. 10 is a process flow diagram illustrating a method for managing sharing of EIS battery testing data according to an embodiment.

FIG. 11A is a graphical representation of an example EIS test input and response that is well correlated to a negative performance event such as overheating.

FIG. 11B is a graphical representation of an example EIS test input and response attribute that is poorly correlated to overheating.

FIG. 12 is a process flow diagram illustrating a method for managing charging of a battery using EIS testing results according to an embodiment.

FIG. 13 is a table illustrating an example battery protection algorithm decision matrix according to an embodiment.

FIG. 14 is a table illustrating an example learned database according to an embodiment.

FIG. 15 is a table illustrating an example charger database according to an embodiment.

FIG. 16A is a table illustrating an example test database according to an embodiment.

FIG. 16B is a table illustrating an example command database according to an embodiment.

FIG. 17 is a component block diagram of server suitable for use with the various embodiments.

### DETAILED DESCRIPTION

Various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the claims.

Many types of batteries are susceptible to degradation from charging and discharging cycles, heat and cold exposure, and aging because of the effects these factors may have on the internal chemistry of batteries. For example, any one or combination of the battery degradation factors may result in deposits of oxidized particles of an electrolyte adhering to an anode and a cathode of a battery. The adhesion of the oxidized particles to the anode and the cathode may reduce a surface area of the anode and the cathode for reacting with the electrolyte, reduce an amount of electrolyte in the battery, and increase the internal resistance of the battery. Battery degradation may result in a reduced power storage capacity, a reduced voltage output, and an increased self-discharge rate. These degradations of a battery's performance may also reduce a useful life of a battery. In some embodiment, battery charging may be managed to improve efficiency, performance, and/or longevity of batteries.

The term “battery” may be used interchangeably herein to refer to a battery pack, which may include any number batteries, a battery, which may include any number of battery cells, and/or a battery cell of a battery. A battery may include any rechargeable wet cell battery, rechargeable dry cell battery, and/or rechargeable solid state battery.

The systems, methods, and devices of the various embodiments enable electrochemical impedance spectroscopy (EIS) (also called AC impedance spectroscopy) to be performed on batteries by power electronics connecting the batteries in parallel to a common load and/or bus.

EIS enables the overall impedance of a battery to be determined by applying a test waveform of varying voltage, varying current, or varying voltage and current to the battery and measuring a voltage or current across the battery at varying sampling frequencies to determine a response waveform of varying voltage, varying current, or varying voltage and current. A test waveform of varying voltage, varying current, or varying voltage and current may be selected to achieve the varying sampling frequencies, such as a waveform with voltage/current oscillations of approximately 1 Hz, may be generated on a line connected to the battery. Such a voltage/current waveform may be generated by rapid switching of the line to load and unload the battery, thereby injecting the test waveform into the battery. The test waveform may be a sine wave or other type pattern of variation with time of voltage, current or voltage and current, and may be selected to achieve desired sampling frequencies for a particular EIS test. A voltage or current of the battery and a resulting phase angle may be measured or determined at a sampling frequency to obtain a response waveform, and the response waveform or the resulting measurements/determinations processed using EIS to determine battery impedances. During EIS testing, a number of different voltage/current waveforms may be applied to the battery to obtain different response waveforms, such as impedance measured at various applied waveform frequencies. For ease of reference, a waveform of varying voltage, varying current, or varying voltage and current applied to the battery is referred to herein and in the claims as a “test waveform” to encompass applied voltage, current and voltage/current waveforms. For ease of reference, measurements of voltage, current or voltage and current across the battery while a test waveform is applied are referred generally and collectively in the specification and the claims as a “response waveform.” By comparing the applied test waveform to the measured or determined response waveform, an impedance response of the battery may be determined at the frequency of the applied test waveform.

Results of the EIS procedure (e.g., the impedance at varying frequencies) may be graphically represented using a Nyquist plot or Bode plot and characteristics of the battery may be determined based on the impedance response of the battery. By comparing the impedance response of the battery being measured to known signatures of impedance responses of batteries with known characteristics, the characteristics of the measured battery may be identified. Characteristics of the battery that may be determined based at least in part on the impedance response include charge conditions (e.g., state of charge), anode conditions, and cathode conditions. Based on the determined characteristics of the battery, a setting of the electrochemical device may be adjusted. Additionally, determined characteristics of the battery may be compared to a failure threshold, and when the characteristics exceed the failure threshold, a failure mode of the battery may be indicated, such as buildup of non-conductive compounds on the anode or cathode, dendritic breakdown of the electrolyte, etc.

In an embodiment, correlations of impedance responses of various types of batteries to charge state and/or various failure modes may be discovered by collecting in data sets the impedance responses (i.e., EIS data) of various batteries along with other indications of charge state and/or failure modes, and then using such data sets to train a learning algorithm (e.g., an artificial intelligence (AI) or neural network model) to create a learned database (i.e., an EIS database) that can be used by an Electrochemical Impedance Spectroscopy Analyzer (EISA). In some embodiments, such a learned database may comprise stored plots of impedance responses and/or stored impedance values of similar batteries correlated with known characteristics. By collecting data from many batteries operating under different operating conditions and charging/discharging profiles, a learned database of battery characteristics can be created that may be generally useful by an EISA for monitoring or diagnosing battery systems encompassing a wide range of battery applications. A learned database may be created for each of a variety of battery types. Further, the process of collecting information on impedance responses of batteries to and charge state and/or failure modes for various types of batteries using such data sets to train a learning algorithm may be performed continuously or periodically so as to refine the learned databases over time. The collection of battery impedance responses (i.e., EIS data), charge state and failure mode and the creation and refinement of learned databases may be performed in a centralized service, such as an EISA network, which may make the learned EISA databases available to EIS systems via a network (e.g., the Internet). In some embodiments, such an EISA network may be cloud-based.

In an embodiment, the power electronics connected to each battery of a group of two or more batteries may compensate for any ripple generated during EIS such that no ripple or a reduced ripple is realized at the common load and/or bus. As one power electronics injects the test waveform into its respective battery, a resulting ripple from that power electronics may be applied to the load and/or bus. To counteract this ripple from the power electronics performing EIS monitoring, an offsetting (or canceling) ripple or ripples may be generated by one or more of the other power electronics. To generate the offsetting (or canceling) ripple or ripples one or more of the other power electronics not presently performing EIS monitoring may inject an offset waveform toward their respective battery resulting in an offsetting ripple being applied to the common load and/or bus connected in parallel to the batteries. The sum of the ripple from the power electronics performing EIS monitoring and the offsetting ripple or ripples from the one or more other power electronics may be a DC output resulting in no ripple at the load and/or common bus.

In another embodiment, other devices connected to the common load and/or bus may compensate for any ripple generated during EIS such that no ripple or a reduced ripple is realized at the common load and/or bus. As discussed above, as one power electronics injects the test waveform into its respective battery, a resulting ripple from that power electronics may be applied to the load and/or bus. To counteract this ripple from the power electronics performing EIS monitoring, an offsetting (or canceling) ripple or ripples may be generated by one or more other device, such as a waveform generator, and injected into the common load and/or bus. To generate the offsetting (or canceling) ripple or ripples one or more other device may apply an offset ripple to the common load and/or bus connected in parallel to the batteries. The sum of the ripple from the power electronics performing EIS monitoring and the offsetting ripple or ripples applied by the other device may be a DC output resulting in no ripple at the load and/or common bus.

In an embodiment, during EIS monitoring the impedance of a battery may be determined as the polar form voltage of the battery over the polar form current of the battery. This may enable a Fourier series calculation to be used to allow for analysis of an imperfect sinusoidal ripple at the fundamental frequency without needing to calculate a full Fast Fourier Transform. This may increase the accuracy of the impedance calculation and decrease the processing time required to determine an impedance response in comparison to impedance determinations made using a full Fast Fourier Transform.

In an embodiment, energy storage devices may be included on the power electronics connected to each battery. Energy storage devices may be any type energy storage devices, such as capacitors, supercapacitors, batteries, etc. In various embodiments, the energy storage devices may be on the output, the input, or windings of the transformer of the power electronics to store ripple energy and discharge the ripple energy out of phase. The energy storage device may reduce the ripple current, or eliminate the ripple current, passing to the bus. The ability to reduce and/or eliminate the ripple current resulting from EIS testing may enable EIS testing using test waveforms with higher frequencies than may be used without the energy storage devices. For example, test waveforms with frequencies at or above 400 Hz may be used, greatly extending the bandwidth of the power electronics to create and analyze test waveforms. Without the energy storage devices, the bandwidth of the test waveform frequencies may be practically limited to frequencies less than the switching frequency of the power electronics. With the energy storage devices, the bandwidth of the test waveform frequencies may extend to frequencies greater than the switching frequency of the power electronics.

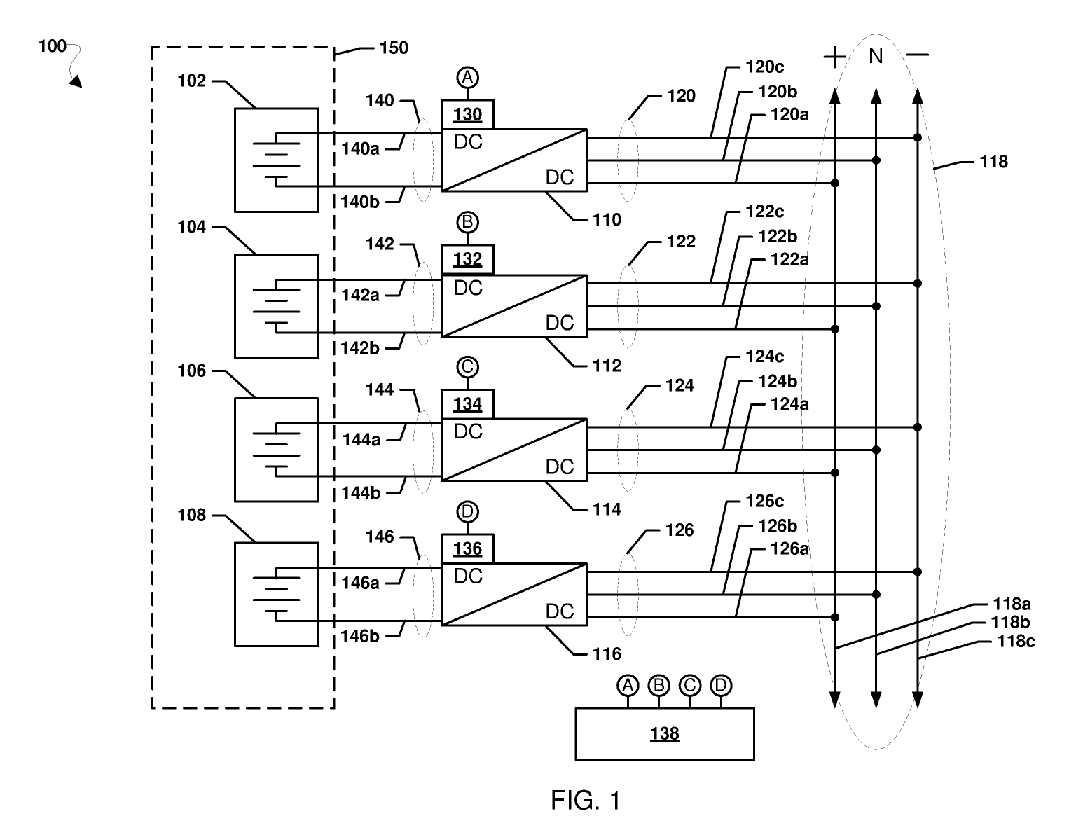

FIG. 1 is a block diagram of a system 100 according to an embodiment. The system 100 may include any number of batteries 102, 104, 106, and 108. For example, the batteries 102, 104, 106, and 108 may each be batteries that may constitute a portion of a power module 150. Each battery 102, 104, 106, and 108 may be electrically connected via a respective input connection 140, 142, 144, and 146 to a respective one of power electronics 110, 112, 114, and 116. Each input connection 140, 142, 144, and 146 may comprise a respective positive input connection 140a, 142a, 144a, and 146a as well as a respective negative input connection 140b, 142b, 144b, and 146b. In operation, the batteries 102, 104, 106, and 108 may output DC voltages to their respective power electronics 110, 112, 114, and 116 via their respective input connections 140, 142, 144, and 146.

The power electronics 110, 112, 114, and 116 may be DC to DC converters. The power electronics 110, 112, 114, and 116 may be each include controllers 130, 132, 134, and 136, respectively, each connected, wired or wirelessly, to a central controller 138. The controllers 130, 132, 134, and 136 may be processors configured with processor-executable instructions to perform operations to control their respective power electronics 110, 112, 114, and 116, and the controller 138 may be a processor configured with processor-executable instructions to perform operations to exchange data with and control the operations of power electronics 110, 112, 114, and 116 via their respective controllers 130, 132, 134, and 136. Via the connections A, B, C, and D between the controllers 130, 132, 134, 136 connected to the power electronics 110, 112, 114, and 116 and the controller 138, the controller 138 may be effectively connected to the power electronics 110, 112, 114, and 116 and control the operations of the power electronics 110, 112, 114, and 116.

The power electronics 110, 112, 114, and 116 may be connected in parallel to a DC bus 118 by their respective output connections 120, 122, 124, and 126. In an embodiment, the DC bus 118 may be a three phase bus comprised of a positive line 118a, a neutral line 118b, and a negative line 118c, and the respective output connections 120, 122, 124, and 126 may include respective positive output connections 120a, 122a, 124a, and 126a, respective neutral output connections 120b, 122b, 124b, and 126b, and respective negative output connections 120c, 122c, 124c, and 126c. In operation, the power electronics 110, 112, 114, and 116 may output DC voltages to the bus 118 via their respective output connections 120, 122, 124, and 126. In an embodiment, power electronics 110, 112, 114, and 116 may be three phase converters configured to receive positive and negative DC inputs from their respective batteries 102, 104, 106, and 108 and output positive DC, negative DC, and neutral outputs to the bus 118 via their respective positive output connections 120a, 122a, 124a, and 126a, respective neutral output connections 120b, 122b, 124b, and 126b, and respective negative output connections 120c, 122c, 124c, and 126c. In an alternative embodiment, power electronics 110, 112, 114, and 116 may each be comprised of dual two-phase converters. The positive output of the first of the two-phase converters may be connected to the positive line 118a of the bus 118 and the negative output of the second of the two-phase converters may be connected to the negative line 118c of the bus 118. The negative output of the first of the two-phase converters and the positive output of the second of the two-phase converters may be connected together to the neutral line 118b of the bus 118.

In an embodiment, the power electronics 110, 112, 114, and 116 may each be configured to perform EIS monitoring of their respective battery 102, 104, 106, and 108. The controller 138 may select a test waveform for use in EIS monitoring for one of the batteries 102, 104, 106, or 108, and may control that power electronics 110, 112, 114, or 116 of that battery 102, 104, 106, or 108 to inject the selected test waveform onto the respective input connection 140, 142, 144, or 146. For example, the controller 138 may send an indication of the selected test waveform to the controller 130 of power electronics 110 to cause opening and closing of a switch at the power electronics 110 to generate the selected test waveform via pulse width modulation on the input connection 140 of connected to the battery 102. The power electronics 110, 112, 114, or 116 injecting the test waveform may be configured to monitor the resulting impedance response of its respective battery 102, 104, 106, or 108, and via its respective controller 130, 132, 134, or 136 may output an indication of the monitored impedance response to the controller 138. Continuing with the preceding example, power electronics 110 may monitor the impedance response on the input connection 140 to the battery 102 and the controller 130 may indicate the impedance response of battery 102 to the controller 138.

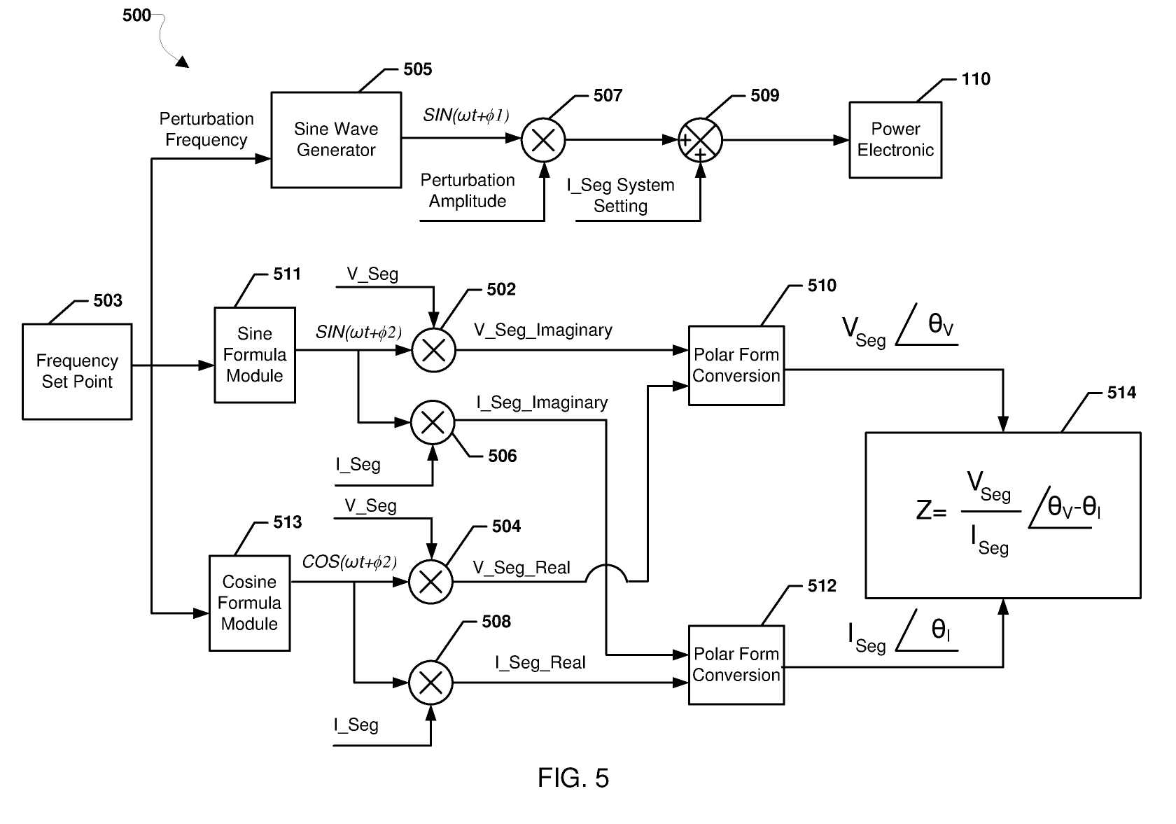

The controller 138 may use the impedance response determined by EIS monitoring of a battery 102, 104, 106, 108 to determine a characteristic of that battery 102, 104, 106, 108 and may adjust a setting of the system 100 based on the determined characteristic. For example, the controller 138 may determine the impedance response according to method 500 described further below with reference to FIG. 5. The controller 138 may compare the impedance response determined by EIS monitoring of a battery 102, 104, 106, 108, such as a plot of the impedance response and/or stored impedance values, to impedance responses stored in a memory, such as stored plots of impedance responses and/or stored impedance values, of similar batteries correlated with known characteristics. The controller 138 may compare the impedance response determined by EIS monitoring of a battery 102, 104, 106, 108 to the stored impedance responses in any manner to identify matches between the impedance responses determined by EIS monitoring of a battery 102, 104, 106, 108 and the stored impedance responses.

When the controller 138 determines a match (e.g., identically or within some predetermined variance value) between the impedance response determined by EIS monitoring of a battery 102, 104, 106, 108 and a stored impedance response, the controller 138 may determine the characteristic correlated with the stored impedance response to be the characteristic of the respective battery 102, 104, 106, 108. For example, EIS monitoring may enable determined characteristics of the batteries 102, 104, 106, or 108 to be compared to charge state characteristics to determine an amount of charge stored in the batteries or whether charging of the batteries is indicated, and a suitable charging operation may be scheduled or commenced. As another example, EIS monitoring may enable determined characteristics of the batteries 102, 104, 106, or 108 to be compared to a failure threshold, and when the characteristics exceed the failure threshold a failure mode of the battery 102, 104, 106, or 108 may be indicated or determined, such as cathode or anode degradation, dendritic degradation of the electrolyte, chemical breakdown of the electrolyte, etc. Based on an indicated or determined failure mode, a suitable response may be indicated or taken, such as adjusting charging and discharging usage of one or more batteries 102, 104, 106, or 108 to extend the useful life of the power assembly 150, adjusting a charging rate and/or a discharging rate to slow or limit further battery degradation, performing a maintenance cycle on one or more of the batteries 102, 104, 106, or 108 (e.g., a deep discharge followed by full recharge), isolating one of the batteries 102, 104, 106, or 108 to prevent failure, and/or indicating that one or more batteries 102, 104, 106, or 108 are reaching end of life and should be replaced. Actions taken in response to an indicated or determined failure mode

When a test waveform is injected on an input connection 140, 142, 144, or 146 by a respective power electronics 110, 112, 114, or 116 to perform EIS monitoring, a ripple on the respective output connection 120, 122, 124, or 126 may occur. If unaccounted for, the resulting ripple from the power electronics 110, 112, 114, or 116 performing EIS monitoring may cause an undesired ripple on the DC bus 118. To prevent a ripple on the DC bus 118, the ripple from the power electronics 110, 112, 114, or 116 performing EIS monitoring may be offset or canceled by other ripples injected into the DC bus 118. In an embodiment, the other ripples may be generated by one or more of the other power electronics 110, 112, 114, or 116 not performing EIS monitoring. The ripples from one or more of the other power electronics 110, 112, 114, or 116 not performing EIS monitoring may be generated by controlling the one or more of the other power electronics 110, 112, 114, or 116 not performing EIS monitoring to inject an offset waveform into their respective input connections to their respective input connections 140, 142, 144, or 146. The offset waveform or waveforms may be selected by the controller 138 such that the ripples on the respective output connections 120, 122, 124, or 126 generated in response to injecting the offset waveform or waveforms cancels the ripple caused by the power electronics 110, 112, 114, or 116 performing EIS monitoring when the waveforms are summed at the DC bus 118. In another embodiment, ripples may be injected into output connections 120, 122, 124, or 126 from devices other than the power electronics 110, 112, 114, or 116 to cancel the ripple caused by the power electronics 110, 112, 114, or 116 performing EIS monitoring when the waveforms are summed at the DC bus 118. For example, a waveform generator may be connected to output connections 120, 122, 124, or 126 to inject canceling ripples in response to EIS monitoring.

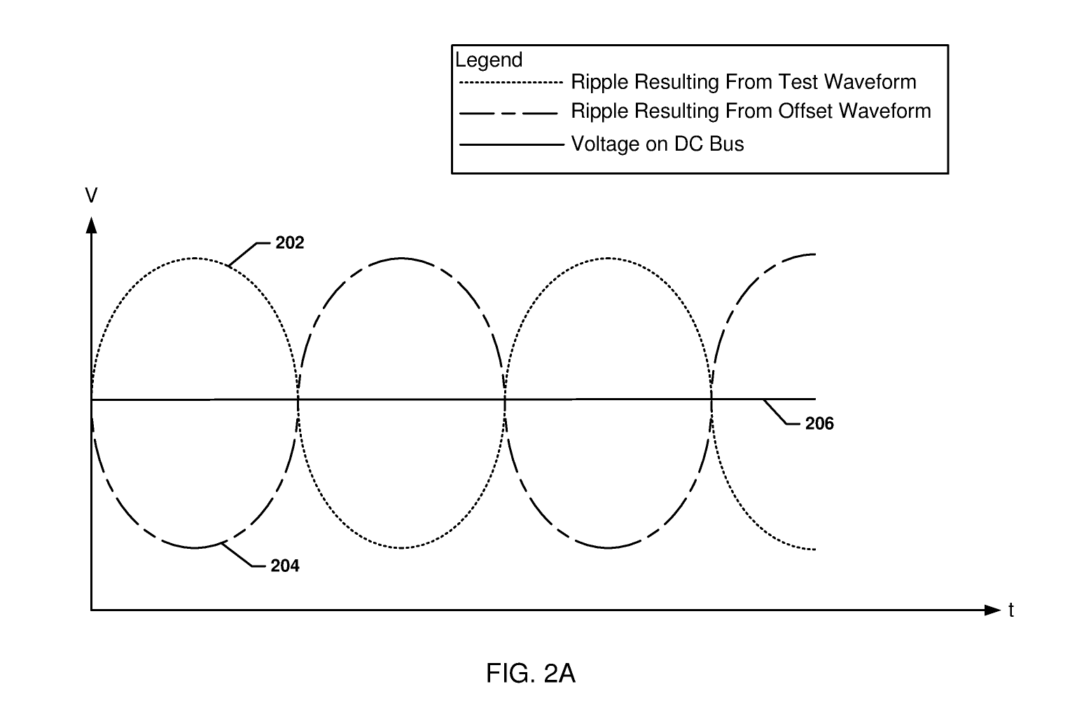

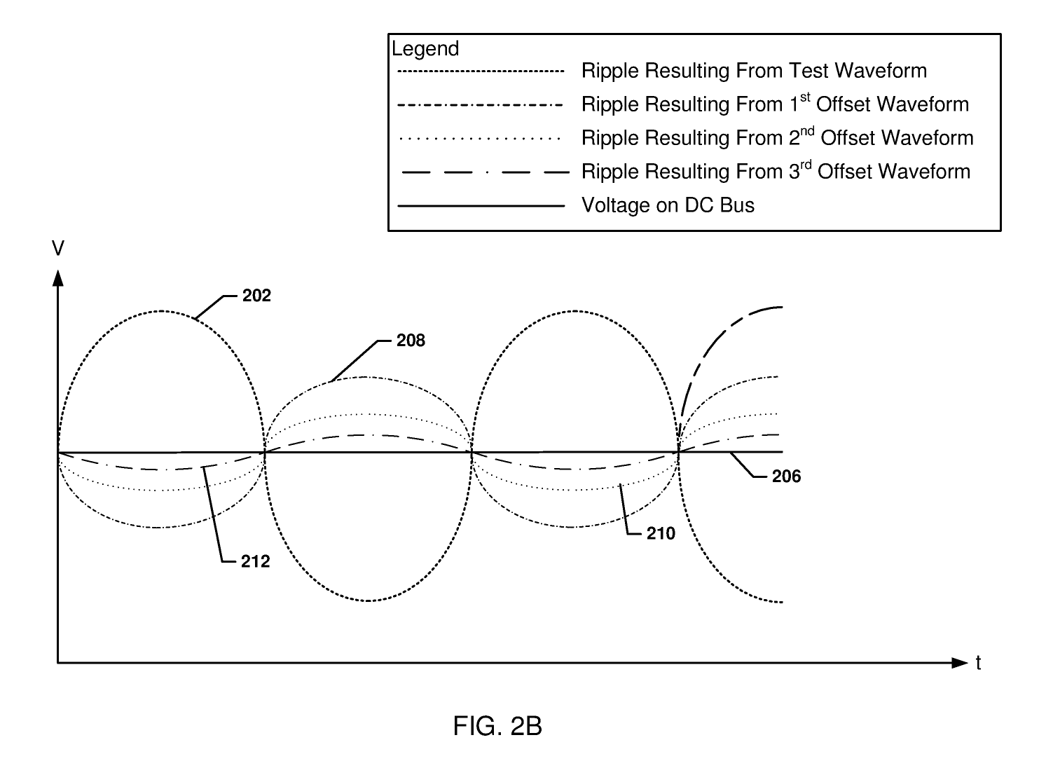

FIG. 2A is a graph illustrating canceling ripples on a DC bus over time. A test waveform injected onto an input connection of a battery by a power electronics may result in a ripple 202 sent from the power electronics injecting the test waveform toward a DC bus. An offset waveform injected onto an input connection of another battery by another power electronics may result in a ripple 204 sent from that power electronics injecting the offset waveform toward the DC bus. The offset waveform may be selected such that the ripple 204 is 180 degrees out of phase with the ripple 202. The power electronics may be connected to the DC bus in parallel and the sum of the ripple 202 and the ripple 204 may cancel each other out such that the sum of the waveforms is the desired DC voltage 206 on the DC bus.

FIG. 2B is another graph illustrating canceling ripples on a DC bus over time using more than one offsetting waveform. As discussed above, a test waveform injected onto an input connection of a battery by a power electronics may result in a ripple 202 sent from the power electronics injecting the test waveform toward a DC bus. Three other power electronics may be used to generate offset waveforms injected onto input connections of three other batteries. The first offset waveform injected onto an input connection of a first other battery by the first other power electronics may result in a ripple 208 sent from that first other power electronics injecting the offset waveform toward the DC bus. The second offset waveform injected onto an input connection of a second other battery by the second other power electronics may result in a ripple 210 sent from that second other power electronics injecting the offset waveform toward the DC bus. The third offset waveform injected onto an input connection of a third other battery by the third other power electronics may result in a ripple 212 sent from that third other power electronics injecting the offset waveform toward the DC bus. The three offset waveforms may be selected such that the sum of the ripples 208, 210, and 212 may cancel ripple 202 such that the sum of the waveforms is the desired DC voltage 206 on the DC bus. While illustrated in FIGS. 2A and 2B as one generated offsetting ripple 204 or three offsetting ripples 208, 210, 212 with the same frequency as the ripple 202, more or less offsetting ripples, with different waveforms, different frequencies, phases, amplitudes, etc. may be generated and injected toward the DC bus as long as the total of any offsetting ripples plus the ripple 202 sent from the power electronics injecting the test waveform toward the DC bus results in the desired DC voltage 206 on the DC bus with no ripple.

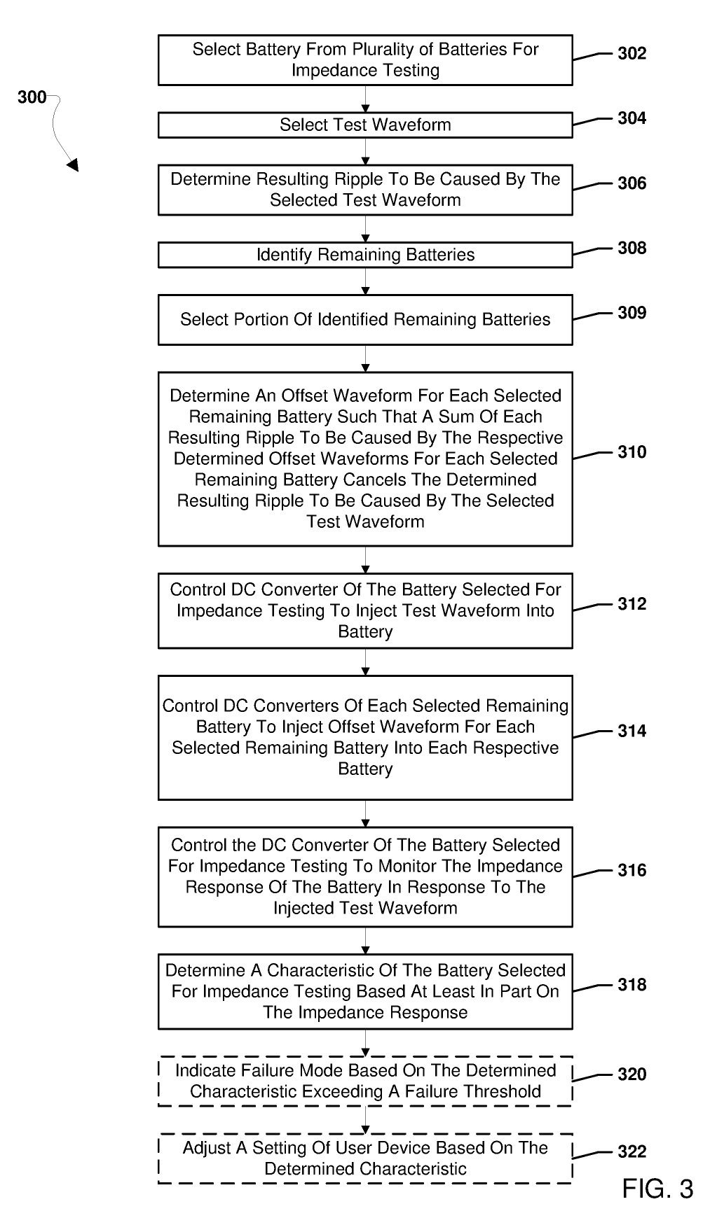

FIG. 3 illustrates an embodiment method 300 for performing an EIS procedure on a battery stack. In an embodiment, the operations of method 300 may be performed by a controller, such as controller 138. The operations of method 300 are discussed in terms of battery stack segments and DC converters, but battery stack segments and converters are used merely as examples. Other batteries and/or other power electronics may be used in the various operations of method 300.

In block 302, the controller 138 may select a battery stack segment from a plurality of battery stack segments for impedance testing. For example, the battery stack segment may be selected based on a testing protocol governing when and in what order battery stack segments may be tested. In block 304 the controller 138 may select a test waveform. The test waveform may be selected to generate necessary oscillations for EIS monitoring, such as oscillations of approximately 1 Hz.

In block 306, the controller 138 may determine a resulting ripple to be caused by the selected test waveform. As discussed above, the resulting ripple may be the ripple output to the DC bus from the DC converter injecting the test waveform. In block 308 the controller 138 may identify the remaining battery stack segments. The remaining battery stack segments may be the battery stack segments not selected for impedance testing. In block 310 the controller 138 may select a portion of the identified remaining battery stack segments. In an embodiment, the selected portion may be all identified remaining battery stack segments. In another embodiment, the selected portion may be less than all identified remaining battery stack segments, such as only a single identified remaining battery stack segment.

In block 310, the controller 138 may determine an offset waveform for each selected remaining battery stack segment such that a sum of each resulting ripple to be caused by the respective determined offset waveforms for each selected remaining battery stack segment cancels the determined resulting ripple to be caused by the selected test waveform. In an embodiment, each offset waveform may be generated such that the resulting ripple is the same, such as one, two, three or more equal ripples that together cancel the ripple from the test waveform. In another embodiment, each offset waveform may be generated such that the resulting ripples are different, such as two, three, or more different ripples that together cancel the ripple from the test waveform.

In block 312, the controller 138 may control the DC converter of the battery stack segment selected for impedance testing to inject the test waveform into the battery stack. For example, the controller 138 may send control signals to a controller (e.g., 130, 132, 134, or 136) of the DC converter to cause the converter to perform pulse width modulation to generate the test waveform on an input connection to the battery stack segment.

In block 314, the controller 138 may control the DC converters of each selected remaining battery stack segment to inject the offset waveform for each selected remaining battery stack segment into each respective battery stack segment. For example, the controller 138 may send control signals to the controllers (e.g., 130, 132, 134, and/or 136) of the DC converters to cause the converters to perform pulse width modulation to generate the offset waveforms on an input connection to their respective battery stack segments.

The operations of the method 300 performed in blocks 312 and 314 may occur simultaneously, such that the test waveform and offset waveforms are injected at the same time resulting in ripples being output from the various DC converters that cancel each other out resulting in a desired DC voltage on the DC bus.

In block 316, the controller 138 may control the DC converter of the battery stack segment selected for impedance testing to monitor the impedance response of the battery stack in response to the injected test waveform. For example, the controller 138 may monitor the voltage and current response of the segment and determine the impedance according to method 500 described below with reference to FIG. 5.

In block 318, the controller 138 may determine a characteristic of the battery stack segment selected for impedance testing based at least in part on the impedance response. For example, the controller may use EIS monitoring to plot the real and imaginary parts of the measured impedances resulting from the injected test waveform and compare the plotted impedances to the known signatures of impedance responses of battery stack segments with known characteristics. The known signatures of impedance responses of the battery stack segments with known characteristics may be stored in a memory available to the controller (e.g., from a learned EIS database provided by an EISA network deployed in the cloud). The stored known signatures of impedance responses of the battery stack segments with known characteristics may be plots of the real and imaginary parts of the measured impedances of healthy battery stack segments and damaged/degraded battery stack segments derived from testing healthy (i.e., undamaged/undegraded) and damaged/degraded battery stack segments with various forms of damage (e.g., anode cracking) and/or degradation (e.g., segments operating in fuel starvation mode). The known characteristics may be correlated with the plots of the real and imaginary parts of the measured impedances stored in the memory. By matching the measured impedances to the known signatures of impedance responses, the current characteristics or state of the battery stack may be determined as those characteristics correlated with the matching known signature of impedance response.

In optional block 320, the controller 138 may indicate a failure mode based on the determined characteristic exceeding a failure threshold. For example, if the determined characteristic exceeds a failure threshold a failure mode of the battery stack may be indicated.

In optional block 322, the controller 138 may adjust a setting of the battery system based on the determined characteristic. For example, the controller 138 may initiate charging adjust a charging or discharging rate (e.g., increase or decrease), or shut off of the battery system based on the determined characteristic. In this manner, impedance testing, such as EIS monitoring, may be used in a battery system to adjust the operation of the battery system based on current characteristics of the battery stack segments.

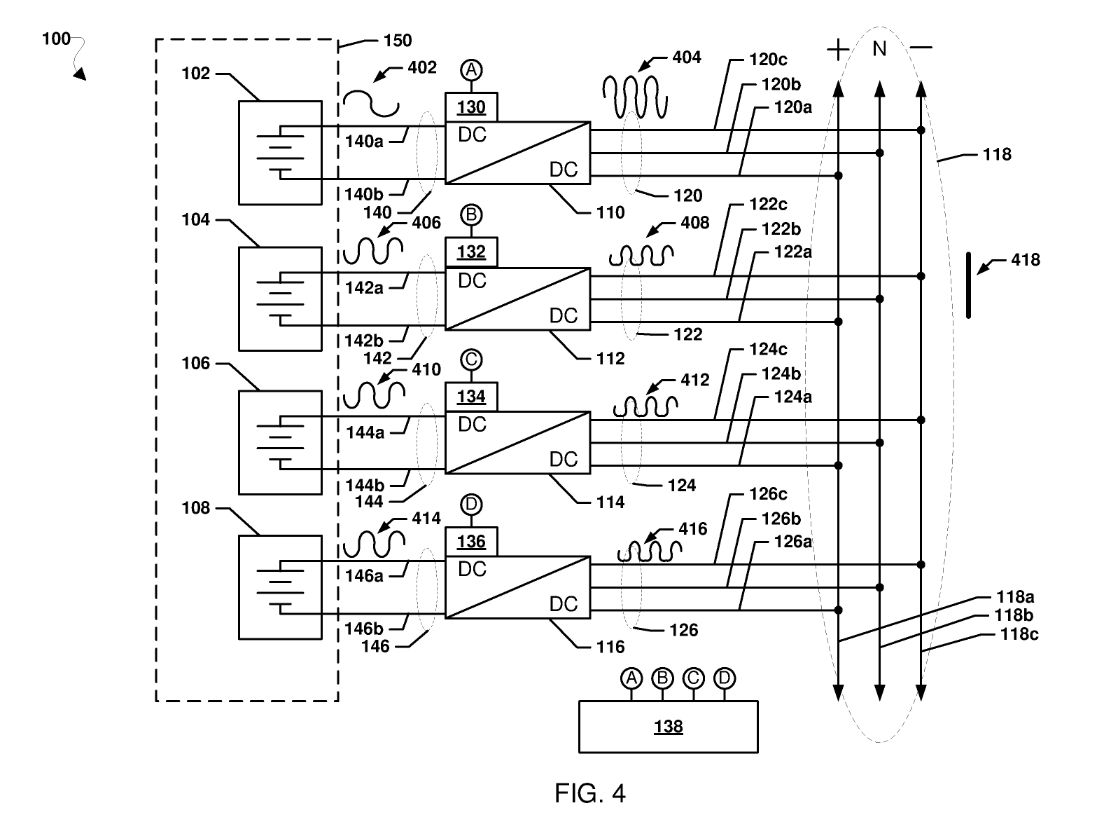

FIG. 4 is a block diagram of the system 100 described above with reference to FIG. 1, illustrating injected waveforms 402, 406, 410, and 414 and resulting canceling ripples 404, 408, 412, and 416 according to an embodiment. A test waveform 402 may be injected into the input connection 140 resulting in a ripple 404 on the output connection 120 to the DC bus 118. An offset waveform 406 may be injected into the input connection 142 resulting in an offset ripple 408 on the output connection 122 to the DC bus 118. An offset waveform 410 may be injected into the input connection 144 resulting in an offset ripple 412 on the output connection 124 to the DC bus 118. An offset waveform 414 may be injected into the input connection 146 resulting in an offset ripple 416 on the output connection 126 to the DC bus 118. The sum of the ripples 404, 408, 412, and 416 may be such that steady DC voltage 418 without a ripple occurs on the

DC bus 118 despite AC ripples occurring on the output connections 120, 122, 124, and 126. While the sum of the ripples 404, 408, 412, and 416 may be such that steady DC voltage 418 without a ripple results on the DC bus 118, the sum of the offset waveforms 406, 410, and 414 and the test waveform 402 need not equal zero. The offset ripples 408, 412, and 416 may all be the same or may be different. For example, offset ripple 408 may be a larger ripple than offset ripples 412 and 416. Additionally, whether or not the offset ripples 408, 412, and 416 are the same or different, the offset waveforms 406, 410, and 414 may not be the same. While three offset waveforms 406, 410, and 414 and their resulting offset ripples 408, 412, and 416 are illustrated, less offset waveforms and offset ripples, such as only two offset waveforms and resulting offset ripples or only one offset waveform and one resulting offset ripple, may be generated to offset the ripple 404.

In an alternative embodiment, the offset ripples 408, 412, and/or 416 may be generated by other devices, such as waveform generators, connected to output connections 122, 124, 126 and controlled by the controller 138, rather than the power electronics 112, 114, and/or 116. The offset ripples 408, 412, and/or 416 may be generated by the other devices such that the sum of the ripples 404, 408, 412, and 416 may be the steady DC voltage 418 without a ripple on the DC bus 118. Additionally, combinations of ripples generated by the power electronics 112, 114, and/or 116 and the other devices, such as additional waveform generators, may be used to cancel the ripple 404 resulting in the steady DC voltage 418 without a ripple on the DC bus 118.

FIG. 5 is a system block diagram illustrating a waveform generator 500 for generating wave forms for performing EIS monitoring of a battery segment. The elements of the waveform generator 500 are discussed in terms of battery stack segments and DC converters, but battery stack segments and converters are used merely as examples. Other batteries and/or other power electronics may be used in the various operations of method 500. In an embodiment, the waveform generator 500 may operate in conjunction with the operations of method 300 described above with reference to FIG. 3.

In an input 503 the controller 138 may input a frequency set point (f) for a particular EIS monitoring process. The frequency set point may be output to a sine wave generator 505 as the perturbation frequency. The sine wave generator 505 may output a waveform SIN(ωt+φ1) in which ω is the fundamental frequency (2πf) and φ1 is the phase angle. In multiplier circuit 507 the output waveform multiplied by the perturbation amplitude, and the result may be added to the segment set as a system setting (I_Seg System Setting) in adder circuit 509 to generate a test waveform that may be sent to the power electronic 110 for injecting the waveform into the battery segment. The current for the segment set as a system setting may be a current setting provided from the controller 138 or another controller as a target current setting for the battery segment. The power electronic 110 illustrated in FIG. 5 may be any one of the power electronics 110, 112, 114, or 116 and similar operations may be performed to control power electronics 112, 114, and 116 to inject test waveforms.

The frequency set point may also be output to a sine formula module 511 and a cosine formula module 513. The sine formula module 511 may output a waveform SIN(ωt+φ2) in which ω is the fundamental frequency (2πf) and φ2 is the phase angle. The cosine formula module 513 may output a waveform COS(ωt+φ2) in which ω is the fundamental frequency (2πf) and φ2 is the phase angle.

In multiplier circuit 502 the output waveform from the sine formula module 511 may be multiplied with the voltage of the segment (V_Seg) to determine the imaginary voltage component of the segment (V_Seg_Imaginary). In multiplier circuit 506 the output waveform from the sine formula module 511 may be multiplied with the current of the segment (I_Seg) to determine the imaginary current component of the segment (I_Seg_Imaginary).

In multiplier circuit 504 may multiply the output waveform from the cosine formula module 513 with the voltage of the segment (V_Seg) to determine the real voltage component of the segment (V_Seg_Real). In multiplier circuit 508 the output waveform from the cosine formula module 513 may be multiplied with the current of the segment (I_Seg) to determine the real current component of the segment (I_Seg_Real).

Module 510 and 512 may respectively convert the real and imaginary components of the voltage of the segment and the real and imaginary components of the current of the segment to polar form voltage of the segment and polar form current of the segment.

Module 514 may determine the impedance “Z” of the segment as the polar form voltage of the segment over the polar form current of the segment. In this manner, the waveform generator 500 may enable a Fourier series calculation to be used to allow for analysis of an imperfect sinusoidal ripple at the fundamental frequency without needing to calculate a full Fast Fourier Transform. This may increase the accuracy of the impedance calculation and decrease the processing time required to determine an impedance response in comparison to impedance determinations made using a full Fast Fourier Transform.

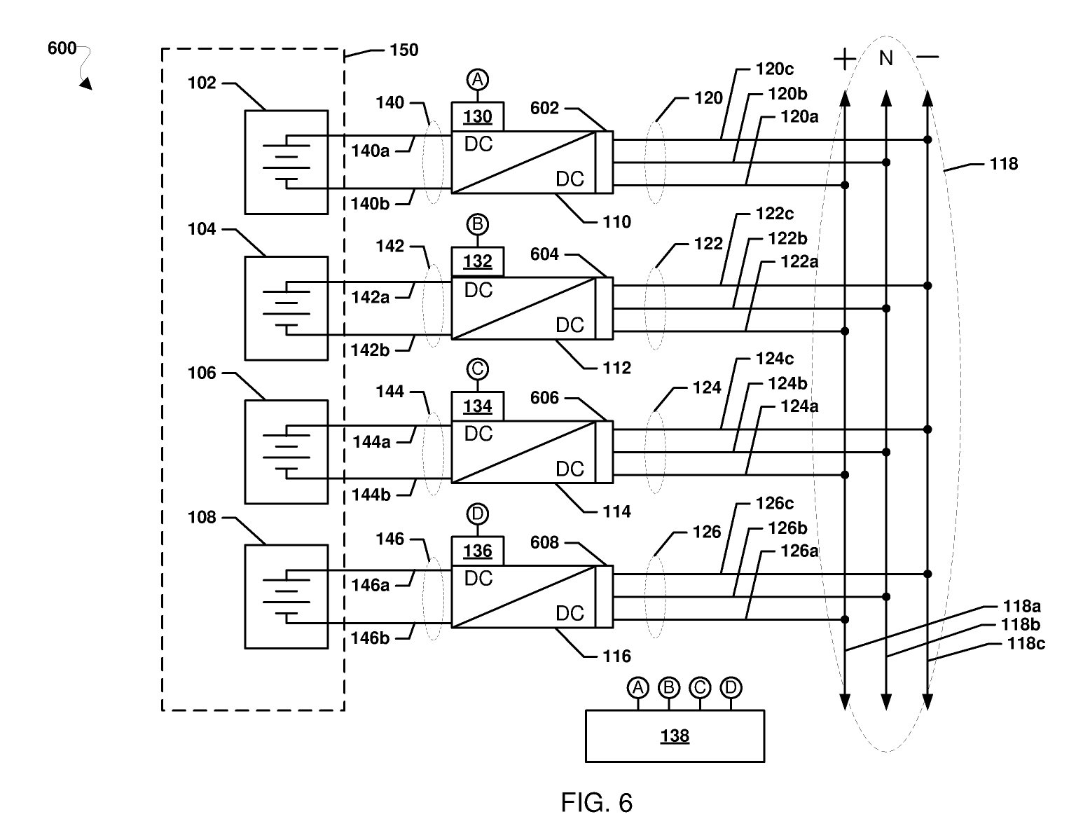

FIG. 6 is a block diagram of a system 600 according to another embodiment. The system 600 is similar to system 100 illustrated in FIG. 1 and includes a number of components in common. Those components which are common to both systems 100 and 600 are numbered with the same numbers in FIGS. 1 and 6 and will not be described further.

The system 600 is similar to the system 100 described above with reference to FIG. 1, except that energy storage devices 602, 604, 606, and 608 may be included on the power electronics 110, 112, 114, and 116, respectively. Energy storage devices 602, 604, 606, and 608 may be any type of energy storage devices, such as capacitors, supercapacitors, batteries, etc. In an embodiment, the energy storage devices 602, 604, 606, and 608 may be on the output of their respective power electronics 110, 112, 114, and 116 to store ripple energy and discharge the ripple energy out of phase. The discharge out of phase by an energy storage device 602, 604, 606, or 608 may provide cancelation of the ripple current output on the respective output connection 120, 122, 124, or 126 to the DC bus 118 as a result of a test waveform injected into the input connection of the power electronic 110, 112, 114, or 116 associated with that energy storage device 602, 604, 606, or 608. In this manner, the energy storage device 602, 604, 606, or 608 may reduce the ripple current, or eliminate the ripple current, passing to the DC bus 118. The ability to reduce and/or eliminate the ripple current resulting from EIS testing may enable EIS testing using test waveforms with higher frequencies than may be used without the energy storage devices 602, 604, 606, or 608. For example, test waveforms with frequencies at or above 400 Hz may be used, greatly extending the bandwidth of the respective power electronics 110, 112, 114, and 116 to create and analyze test waveforms. Without the energy storage devices 602, 604, 606, or 608, the bandwidth of the test waveform frequencies may be practically limited to frequencies less than the switching frequency of the power electronics 110, 112, 114, and 116. With the energy storage devices 602, 604, 606, or 608, the bandwidth of the test waveform frequencies may extend to frequencies greater than the switching frequency of the power electronics 110, 112, 114, and 116.

While illustrated as on the output of their respective power electronics 110, 112, 114, and 116 in FIG. 6, the energy storage devices 602, 604, 606, and 608 may be on any other portions of their respective power electronics 110, 112, 114, and 116 to store ripple energy and discharge the ripple energy out of phase. In an alternative embodiment, the energy storage devices 602, 604, 606, and 608 may be on the input of their respective power electronics 110, 112, 114, and 116 to store ripple energy and discharge the ripple energy out of phase. In another alternative embodiment, an additional winding may be added to the transformers of the energy storage devices 602, 604, 606, and 608 and the energy storage devices 602, 604, 606, and 608 may be connected to the additional winding to store ripple energy and discharge the ripple energy out of phase.

EIS helps in understanding electrochemical processes by analyzing reflected electric signals that result when small, variable frequency electric signals are sent as test signals towards a battery or circuit under test.

Batteries' performance and health may be tested and characterized by analyzing the responses of batteries against different types of input waveforms (electric signals) using EIS.

U.S. Pat. No. 9,461,319, incorporated herein by reference in its entirety, teaches a method of performing EIS on fuel cells. A microcontroller, as shown part of EIS system, may perform EIS tests with the help of a tester circuit. A microprocessor may apply and control the type of waveform and time of application, frequency of the signal and other associated parameters. A battery may act as load to the input signals (small voltage signals). The output or response of the battery may be measured and stored. This data may be indicative of the state of the battery. For example, a 110 Hz sinusoidal signal may return as a chopped 105 Hz signal. The changes to the input signal may be a manifestation of changes happening inside the battery. The internal changes in the battery could be due to change in diffusion rate of ions at the electrode of the battery or due to wear and tear around the anode contact to the battery cells.

In some embodiments, an electrochemical impedance spectroscopy analyzer (EISA) may be used to prevent dangerous battery levels. An EISA may implement real time EISA testing and learning for performance enhancement and danger prediction. The EISA may apply a matrix of parameters or a switch to test batteries in real time in order to provide information to enhance battery operation to stay in high performance states, and to predict danger and turn off a device including the battery.

In some embodiments, a method may use various testing parameters while using EISA testing and learning in order to determine preferred operating parameters for a battery to stay in high performance states, and using EISA testing collected data to determine a threshold result that may create a danger status for the battery. Once this threshold is reached, the battery may be halted and the consumer device may turn off to prevent any dangerous malfunctions.

This method may be implemented on any battery-operated device to provide an additional level of safety to make sure the battery does not exceed normal operating levels to prevent any hazardous events.

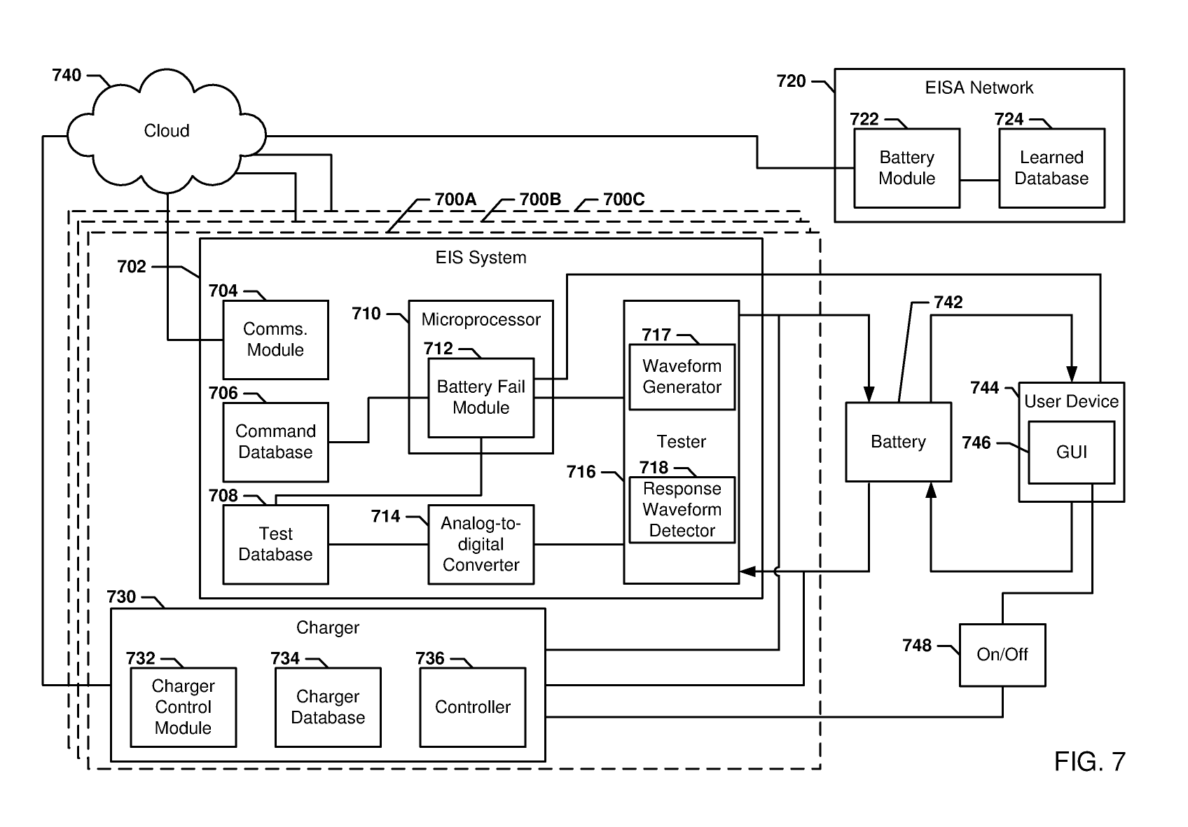

FIG. 7 illustrates an example of a plurality of systems 700A, 700B, 700C according to an embodiment, each of which include an example EIS system 702 described in U.S. Pat. No. 9,461,319, incorporated herein by reference in its entirety. Each system 700A, 700B, 700C may include a charger 730 for a respective battery 742. Each charger 730 may be connected to the respective battery 742. Each battery 742 may be connected to a battery powered device 744 (such as laptop, mobile phone, an electric vehicle, etc.). A respective device battery 742 may be connected to each EIS system 702 of the systems 700A, 700B, 700C. Each of the systems 700A, 700B, 700C may be communicatively connected to an EISA network 720 via the Internet 740, such as in a cloud deployment.

The EIS system 702 may allow running of an EIS test at the convenience of the charger 730. The EIS 702 system may include a battery fail module 712 configured to extract a command from a command database 706, which may contain various commands for an EIS system battery tester circuit 716, such as real time waveforms of voltage/current outputs, times for voltages/current, etc. The battery tester circuit 716 may include a test waveform generator 717 configured to apply EIS test waveforms to the battery 742, and a response waveform detector 718 configured to measure voltage and/or current across the battery at sampling intervals to determine response waveforms. The battery fail module 712 may send the command to the battery tester circuit 716, measure a voltage/current that comes back to the battery tester circuit 716, receive an output voltage/current, and store all of the data in a test database 708. The command database 706 and the database 708 may be stored on any combination of persistent or volatile memories of the EIS system 702

The EIS system 702 may include a communication module 704, represented as “Comms. Module” in FIG. 7, which may allow the EIS system 702 to communicate with the EISA network 720. The communication module 704 may support both wired and wireless communication capabilities such as Ethernet, WIFI, Bluetooth, etc. The battery fail module 712 may connect to an EISA network battery module 722 and send the data from the test database 708 to the EISA network battery module 722.

The EISA network battery module 722 may connect to the EIS system 702 and receive the data from the EIS system test database 708. The EISA network battery module 722 may store the data in an EISA network learned database 724, which may contain historical data from other EIS systems 702 from other battery-powered devices 744 that includes a type of device, a voltage input and output, a current input and output, ohms, a current battery level, if an error occurred on the battery 742, and a result of the occurred error (e.g., holds shorter charge, overheats, etc.).

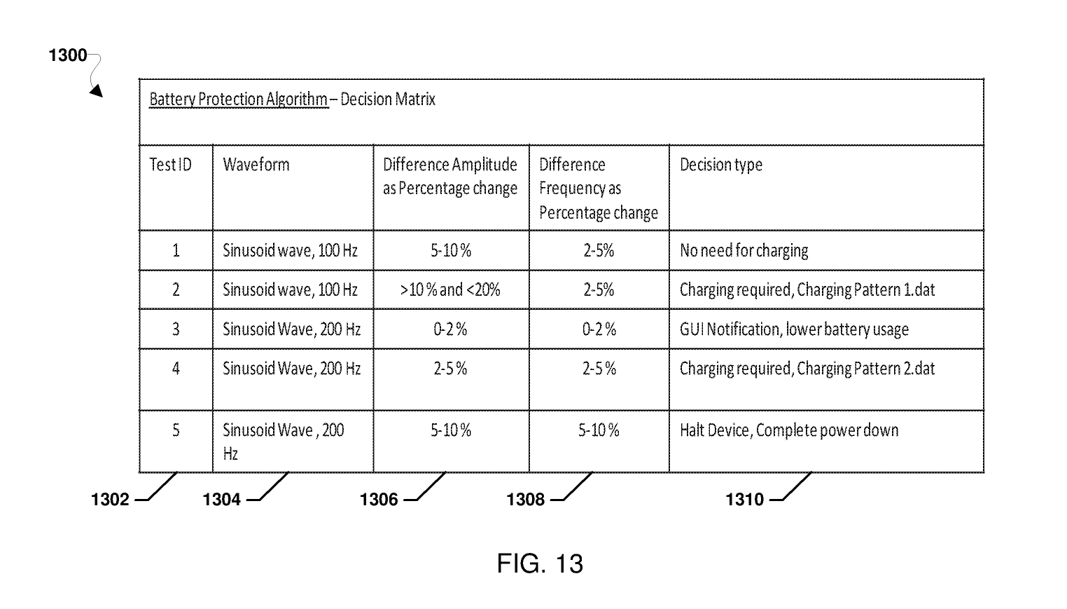

The battery fail module 722 uses an algorithm in order to determine a preferred operating voltage/current that should be applied to the device battery 742 that may prevent the device battery from degrading, such as holding a shorter charge, overheating, exploding, or any dangerous outcomes. The algorithm may create a lookup table or matrix of potential actions, as discussed further herein with reference to FIG. 13, for various states of the battery 742. The battery fail module 722 may send an appropriate action from the lookup table or matrix to a charger controller 736, which may be configured to turn on or turn off the device charger 744 in order to maintain the safety of the battery 742. In some embodiments, in response to the battery states reaching a particular threshold that is related to a dangerous potential for the battery to catch on fire (from the historical data), the battery fail module 722 could send the appropriate action to the device battery 742 directly, or notify a user through a battery-powered device graphical user interface (GUI) 746, to halt charging or discharging of the battery 742 before the any dangerous malfunctions occur. The GUI 746 may be used to tell the user what is going on with the battery-powered device 744. The GUI 746 may be used to provide battery condition information to a user based on EIS tests from the battery fail module 712. In response to the user being unreachable (e.g., asleep, away from device, etc.) the battery fail module 722 may perform a permanent turn off until the battery 742 is checked out by the user or an original equipment manufacturer (OEM).

In some embodiments, the battery 742 and the charger 730 may be separable or integrated components of the battery-powered device 742. The charger 730 may include a controller 736 for controlling charging, which may be configured to start charging when connected to alternating current (AC) power, and discontinue charging when the battery charge state reaches 100%. The charger 730 may include a charger database 734 for maintaining charge parameters that may be preloaded or downloaded from the cloud 740 using a charger control module 732. The charger database 734 may be stored on a persistent or volatile memory of the charger 730.

In some embodiments the EIS system 702 may be separable and/or integrated component of the battery-powered device 746 and/or its battery 742. The battery fail module 712 may run EIS tests periodically, using the EIS system 702, to understand the battery performance.

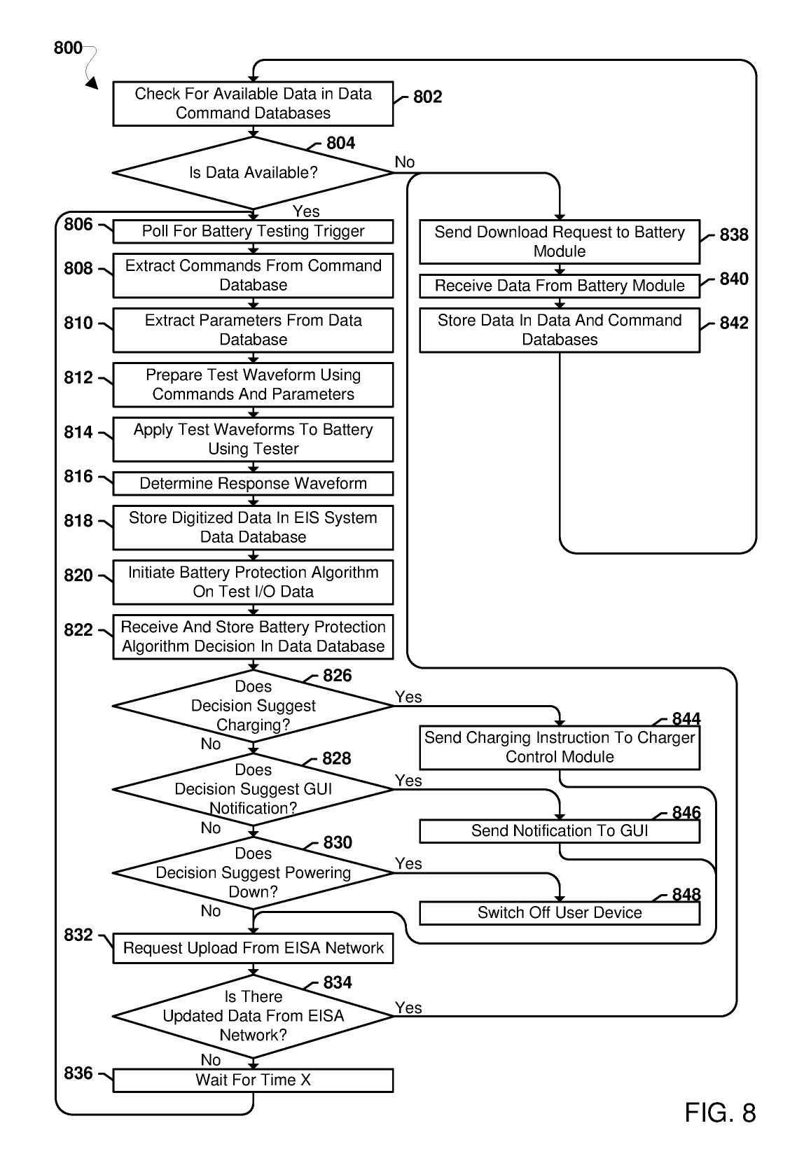

FIG. 8 illustrates a method 800 for EIS testing and protection of a battery according to an embodiment. An EIS system battery fail module (e.g., battery fail module 712) may be configured to perform EIS tests. The battery fail module may poll a battery (e.g., battery 742 in FIG. 7) periodically, for example every ten minutes, and/or continuously. The battery fail module may extract commands for generating EIS test waveforms from an EIS system command database (e.g., command database 706 in FIG. 7) and waveform parameters from an EIS system test database (e.g., test database 708 in FIG. 7). The battery fail module may apply the EIS test waveforms to the battery via a tester (e.g., battery tester circuit 716 in FIG. 7). An EIS test could be a group of individual EIS tests with different frequencies, amplitudes, and power densities of waveforms. A response waveform may be received by the tester and converted into a digital signal using an analog-to-digital converter (e.g., analog-to-digital converter 714 in FIG. 7). The battery fail module may store the digital response data in the EIS system test database.

The EIS system battery fail module may check the results of the EIS test and infer a state of the battery. The EIS system battery fail module may run a battery protection algorithm on the test data (e.g., input and/or output data) and create a decision on a charging procedure for a battery-powered device (e.g., battery-powered device 744 in FIG. 7), which may be based on a lookup table or decision matrix as described further herein with reference to FIG. 13. The decision may be stored in the EIS system test database. A battery protection algorithm may be used to infer that the battery is doing fine and, thus, the decision may be that there is no need for any instruction for the battery charger (e.g., charger 730 in FIG. 7) or a device GUI (e.g., GUI 746 in FIG. 7). However, in response to a pattern recognized that indicates a bad/undesired or dangerous situation based on analysis of the sent and received waveform, the EIS System battery fail module may try to counter the indicated situations. The decision could be to alternate between charger “ON/OFF” states until the situation fades away, or to notify a user about the situation and ask for reduction in heavy user activity (such as suggesting lowering of display brightness, turning WiFi off, etc.) until the situation fades away. The EIS system battery fail module may wait for a predetermined amount of time (e.g., 10 minutes) and may loop back to poll for a battery testing trigger to test the battery again. A period of the polling may be increased and/or decreased based on a severity and rate of fading of the situation. In response to the battery remaining vulnerable after the above two types of measures, the decision may be to instruct the user to turn off or halt the battery-powered device completely and get the battery checked by an OEM service center. In response to the user not responding to the halting recommendation, the EIS system battery fail module may automatically turn the device to an “OFF” state. This may be useful to counter cases when the user is not able to respond to the halting advice (such as when asleep or away).

The method 800 may be implemented in software executing in a software-configurable processor (such as a central processing unit, graphics processing unit, etc.), in general purpose hardware, in dedicated hardware, or in a combination of a software-configured processor and dedicated hardware, such as a processor executing software within a system for EIS testing (e.g., system 700A, 700B, 700C, EIS system 702 in FIG. 7), and various memory/cache controllers. In order to encompass the alternative configurations enabled in various embodiments, the hardware implementing the method 800 is referred to herein as a “control device.”

In block 802, the control device may check for available data in an EIS system test database and an EIS system command database. The control device may have battery identifying information for a connected battery. Battery identifying information may include any information that may be used to identify the battery, such as any combination of a battery identifier, a battery size, a battery power capacity, a battery chemical composition, a battery brand, a battery-powered device to which the battery is coupled (also referred to herein as a battery powered device), etc. The control device may use the battery identifying information to request and retrieve data on and/or from entries associated with the battery identifying information in the EIS system databases.

In determination block 804, the control device may determine whether data is available in the EIS system test database and the EIS system command database. Responses to requests for data from the EIS system databases may include data, a data indicator (such as a general confirmation of available data, a specific number of entries with available data, identification of entries with available data), no data, a no data indicator (such as a response of “0” entries or a null value), and/or an error. In response to receiving a response with data or a data indicator, the control device may determine that there is data available for the battery in the responding EIS system database. In response to receiving a response with no data, a no data indicator, and/or an error, the control device may determine that there is no data available for the battery in the responding EIS system database.

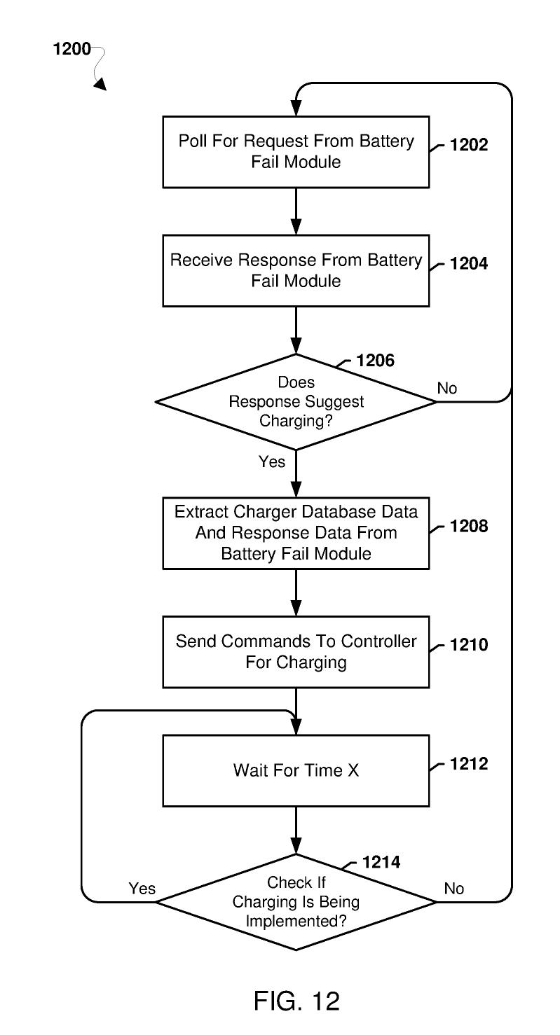

In response to determining that there is data available the EIS system test database and the EIS system command database (i.e., determination block “804”=Yes), the control device may poll for a battery testing trigger in block 806. The battery testing trigger may be a signal from the charger to run an EIS test on the battery. The request may instruct the control device to run an EIS test on the battery. Requesting an EIS test on the battery by the charger is discussed further herein for the method 1200 described with reference to FIG. 12. The control device may check a communication interface, such as communication port or communication module (e.g., comms. module 704 in FIG. 7) of the EIS system, for a request from the charger.

In block 808, the control device may extract commands from the EIS system command database. The control device may use the battery identifying information to request and retrieve data, including EIS testing commands, from entries associated with the battery identifying information in the EIS system command database.

In block 810, the control device may extract data from the EIS system test database. The control device may use the battery identifying information to request and retrieve data, including EIS test waveform parameters, from entries associated with the battery identifying information in the EIS system test database.

In block 812, the control device may prepare an EIS test waveform using the EIS testing commands and the EIS test waveform parameters. The control device may use the EIS test waveform parameters to generate the EIS test waveform and use the EIS testing commands to determine how long to generate the EIS test waveform. The control device may load the EIS test waveform parameters and the EIS testing commands and use the EIS test waveform parameters and the EIS testing commands to signal an analog-to-digital converter with digital signals of instructions for generating the EIS test waveform.

In block 814, the control device may apply the EIS test waveform to the battery using the tester. The control device may send the digital signals of instructions for generating the EIS test waveform to the analog-to-digital converter so that the analog-to-digital converter may convert the digital signals to analog signals. The analog signals may be provided by the analog-to-digital converter to a tester, which may respond to the analog signals by generating an EIS test waveform according to the instructions of the analog signals. The tester may apply the generated EIS test waveform to the battery coupled to the EIS system. The tester may apply the generated EIS test waveform to the battery for a period as indicated by the analog signals and may cease generating the EIS test waveform upon expiration of the period.

In block 816, the control device may receive an EIS response waveform from the tester, which may determine the response waveform by measuring voltage or current across the battery at a sampling interval. The tester may provide the measurements of voltage or current at the sampling interval to the analog-to-digital converter, which may convert the analog voltage or current samples to digital values that the control device may use to determine the response waveform.

In block 818, the control device may store the digitized data in the EIS system test database. The control device may store the digital response waveform to the EIS system test database. In some embodiments, the control device may format the digital response waveform as a digital data file, such as a “.dat” format file. The control device may store the digital response waveform to the EIS system test database in a manner that enables the digital response waveform to be associated with battery identifying information in the EIS system test database for the tested battery.

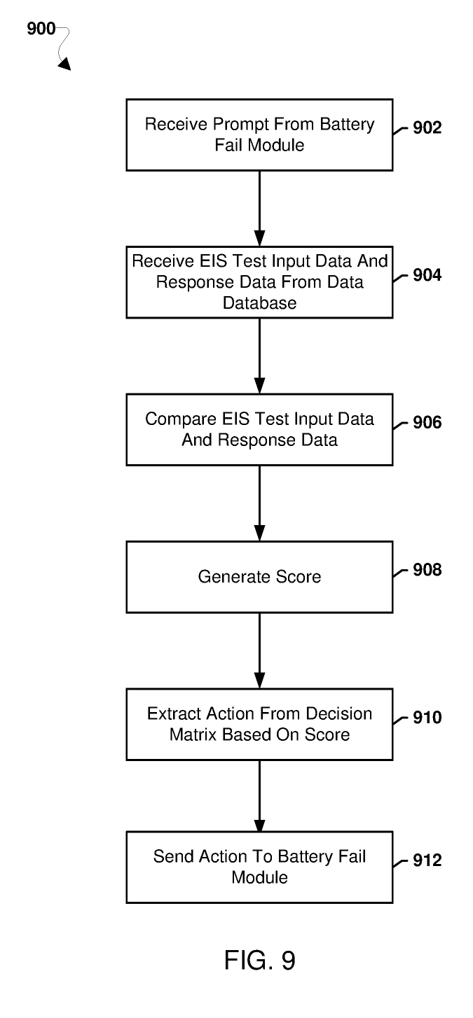

In block 820, the control device may initiate a battery protection algorithm using the EIS test input and output data. The control device may execute the battery protection algorithm using the EIS testing commands, the EIS test waveform parameters, and/or the digital response waveform as inputs to the battery protection algorithm. The battery protection algorithm may generate a battery protection recommendation. The battery protection algorithm in the method 900 described with reference to FIG. 9.

In block 822, the control device may receive and store a battery protection algorithm decision in the EIS system test database. The battery protection algorithm decision may include the battery protection recommendation. The control device may store the battery protection algorithm decision to the EIS system test database in a manner that enables the battery protection algorithm decision to be associated with battery identifying information and/or the digital response waveform in the EIS system test database for the tested battery.

In determination block 826, the control device may determine whether the battery protection algorithm decision suggests charging the battery. The battery protection algorithm decision may include a suggestion to charge the battery, including parameters or a pattern for charging the battery.

In response to determining that the battery protection algorithm decision suggests charging the battery (i.e., determination block 826=“Yes”), the control device may send charging instructions to a charger control module (e.g., charger control module 732 in FIG. 7) in block 844. The charging instructions may include an instruction to charge and parameters or a pattern for charging the battery.

In response to determining that the battery protection algorithm decision does not suggest charging the battery (i.e., determination block 826=“No”), the control device may determine whether the battery protection algorithm decision suggests a GUI notification in determination block 828. The battery protection algorithm decision may include an instruction to send an instruction to the battery-powered device to provide message to a user via the GUI with instructions on use of the battery-powered device.

In response to determining that the battery protection algorithm decision suggests a GUI notification (i.e., determination block 828=“Yes”), the control device may send the GUI notification to the battery-powered device in block 846.

In response to determining that the battery protection algorithm decision does not suggest a GUI notification (i.e., determination block 828=“No”), the control device may determine whether the battery protection algorithm decision suggests powering down the battery-powered device in determination block 830. The battery protection algorithm decision may include an instruction to send an instruction to the battery-powered device to power down. The instruction may be to power down the battery-powered device temporarily, permanently, or until the battery is inspected by an OEM service provider.

In response to determining that the battery protection algorithm decision suggests powering down the battery-powered device (i.e., determination block 830=“Yes”), the control device may send the battery-powered device power down instruction to the battery-powered device in block 848. In some embodiments, the control device may disconnect the battery from the battery-powered device in block 848, such as by opening a switch (e.g., on/off switch 748 of FIG. 7).

In response to determining that the battery protection algorithm decision does not suggest powering down the battery-powered device (i.e., determination block 830=“No”); following sending the charging instructions to the charger control module in block 844; or in following sending the GUI notification to the battery-powered device in block 846, the control device may request an upload from an EISA network (e.g., by sending the request to the battery module 722 in FIG. 7) in block 832. In some embodiments, the upload request may include any combination of: battery identifying information of the tested battery; EIS testing information, which may include any combination of an EIS test identifier, EIS test waveform parameters, EIS testing commands, and/or the digital response waveform; performance parameters of the battery; and/or charger identifying information.

In block 834, the control device may determine whether there is updated data from the EISA network (e.g., EISA network 720 in FIG. 7). The control device may request updated data from the EISA network. In some embodiments, the control device may indicate to the EISA network a version of data the control device has and request for updates that are newer than the version. The response or lack of response from the EISA network may indicate to the control device whether there is updated data.

In response to determining that there is not updated data from the EISA network (i.e., determination block 834=“No”), the control device may wait for a time “X”. The time “X” may be any amount of time.

In block 806, the control device may poll for a battery testing trigger.

In response to determining that there is no data available the EIS system test database and/or the EIS system command database (i.e., determination block “804”=No); or in response to determining that there is updated data from the EISA network (i.e., determination block 834=“Yes”), the control device may send a download request to the EISA network battery module in block 838. The download request may include any combination of battery identifying information and charger identifying information.

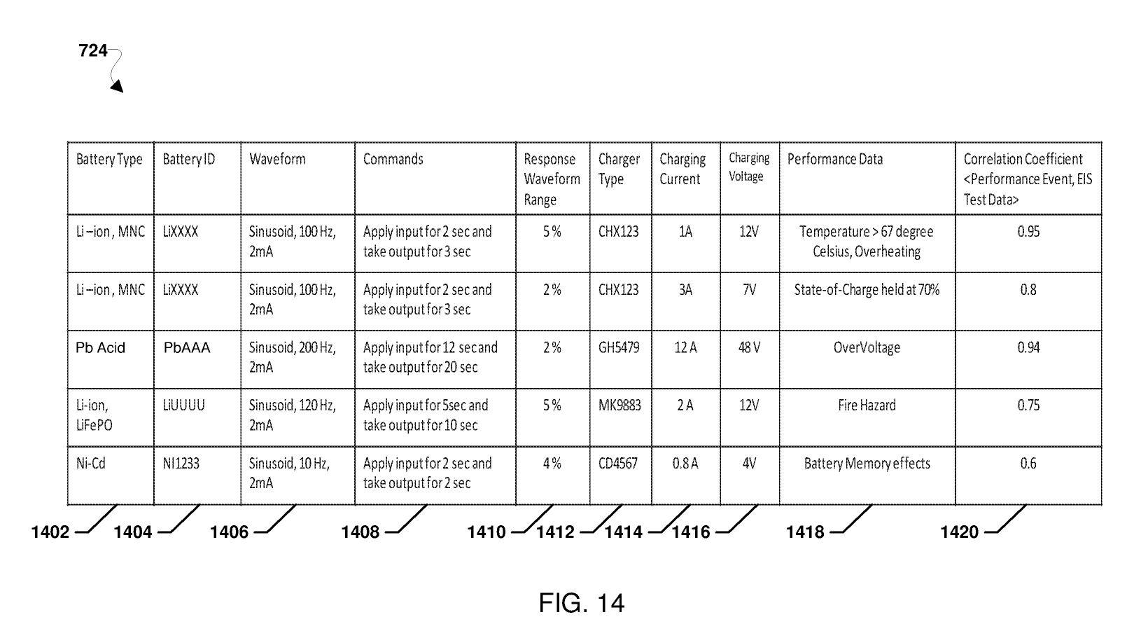

In block 840, the control device may receive data from the EISA network battery module. The data may include entire and/or partial entries of an EISA network learned database (e.g., learned database 724 in FIG. 7). The EISA network learned database is discussed further herein with reference to FIG. 14.

In block 842, the control device may store the data received from the EISA network battery module in the EIS system test database and the EIS system command database. The control device may store the data to the EIS system test database and the EIS system command database in a manner such that the data may be associated with battery identifying information in the EIS system test database and the EIS system command database for the appropriate battery.

In block 802, the control device may check for available data in an EIS system test database and an EIS system command database.

FIG. 9 illustrates a method 900 for making a battery protection recommendation using EIS testing results according to an embodiment. A battery protection algorithm module may be implemented as part of a microprocessor (e.g., microprocessor 710 in FIG. 7) or a specific module outside the microprocessor.

The battery protection algorithm module may be initiated by an EIS system battery fail module (e.g., battery fail module 712 in FIG. 7). The battery protection algorithm module may take into account input and output data from an EIS system test database (e.g., test database 708 in FIG. 7) and check if a response waveform to an EIS test is within certain predefined or learned ranges for safe and/or unsafe operation of a battery (e.g., battery 742 in FIG. 7). Decisions and actions based on the predefined or learned ranges can be pre-loaded or downloaded from an EISA network learned database (e.g., learned database 724 in FIG. 7) as part of downloading data for the EIS system test database.

The battery protection algorithm module may compare the input waveform (or EIS test waveform) and reflected waveform (or response waveform). The comparison may be represented as a number or score as a percentage of a difference between the input and reflected waveforms to the input waveform. The comparison may also be represented in terms of any other parameters associated with an EIS test and/or a performance event that is being countered. Based on the score, the battery protection algorithm module may instruct the battery fail module to take action or not.

A decision could also be an outcome of an aggregate decision based on plurality of EIS tests according to plurality of waveforms. The decision might be taken based on majority of outcomes. For example, three out of four EIS tests may indicate “switch off the device” as a decision for the respective EIS tests, and the aggregate decision may align with the majority of the decisions. In response to the aggregate decision, powering down of the device may be conducted and the minority, fourth decision may be ignored.

The method 900 may be implemented in software executing in a software-configurable processor (such as a central processing unit, graphics processing unit, etc.), in general purpose hardware, in dedicated hardware, or in a combination of a software-configured processor and dedicated hardware, such as a processor executing software within a system for EIS testing (e.g., system 700A, 700B, 700C, EIS system 702 in FIG. 7), and various memory/cache controllers. In order to encompass the alternative configurations enabled in various embodiments, the hardware implementing the method 900 is referred to herein as a “control device.”

In block 902, the control device may receive a prompt from a battery fail module. The prompt may indicate that the battery fail module is conducting and/or has conducted an EIS test. In some embodiments, the prompt may be configured to trigger initiation of a battery protection decision. In some embodiments, the prompt may include any combination of battery identifying information and EIS testing information.

In block 904, the control device may receive EIS test input data and response data from an EIS system test database. The EIS test input data may include EIS test waveform parameters and the response data may include a digitized response waveform stored in the EIS system test database in association with each other. In some embodiments, the control device may be provided with the EIS test waveform parameters and response waveform. In some embodiments, the control device may retrieve the EIS test waveform parameters and response waveform using information received with the prompt in block 902.

In block 906, the control device may compare the EIS test input data and the response data. The control device may compare the response waveform and the EIS test waveform to determine a difference between the waveforms. The difference may be in the form of a frequency difference, an amplitude difference, a phase shift, etc.

In block 908, the control device may determine a score (e.g., a measure of difference) based on the comparison of the EIS test waveform and the response waveform. The comparison of the EIS test waveform and the response waveform may be represented as a number or score as a percentage of differences between the EIS test waveform and the response waveforms to the EIS test waveform. In some embodiments, the score may be a measure of a difference (e.g., measured as a fraction or percentage) in one or more of amplitude, frequency, or phase of the response waveform compared to the EIS test waveform.

In block 910, the control device may extract an action from a lookup table or decision matrix based on the score. The score may be compared to predefined or learned ranges for the difference determined in block 906. The control device may extract an action associated with a predefined or learned range in the decision matrix for the predefined or learned range in which the score falls. An example of a decision matrix is described further herein with reference to FIG. 13.

In block 912, the control device may send the action to the battery fail module. The action may contain instructions for instructing a charger (e.g., charger 230 in FIG. 7) to interact with a battery and/or a battery-powered device (e.g., battery-powered device 744 in FIG. 7).

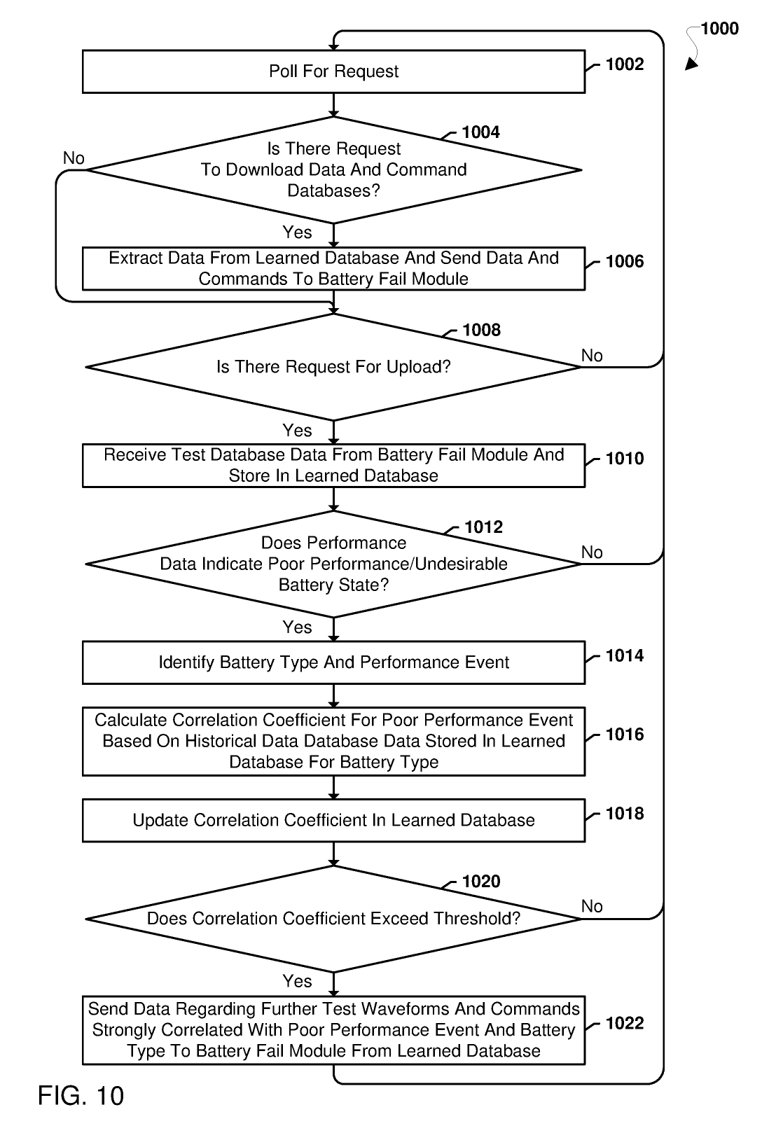

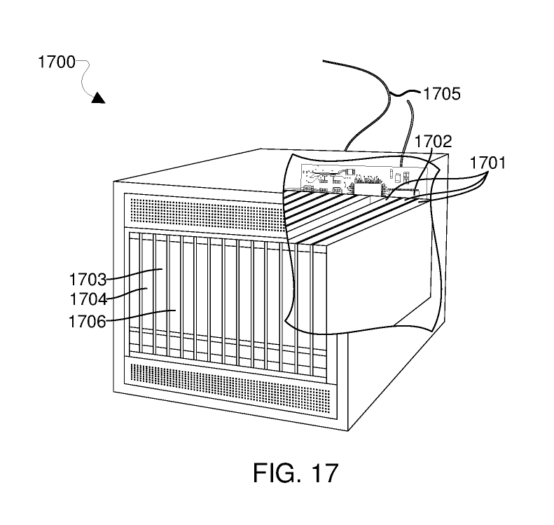

FIG. 10 illustrates a method 1000 for managing sharing of EIS battery testing data according to an embodiment. An EISA network battery module (e.g., battery module 722 in FIG. 7) and a server (e.g., server 1700 in FIG. 17) within an EISA network (e.g., ESIA network 720 in FIG. 7) may poll for requests from EIS systems (e.g., EIS system 702 in FIG. 7) of battery-powered devices (e.g., battery-powered device 744 in FIG. 7). In addition to receiving a request, the EISA network battery module may also receive data indicative of the type of battery. The EISA network battery module may access an EISA network learned database (e.g., learned database 724 in FIG. 7) to extract relevant data specific to the type of battery. In response to the EISA network learned database having relevant data, the relevant data may be sent to an EIS system battery fail module (e.g., battery fail module 712 in FIG. 7) to store the data in an EIS system command database (e.g., command database 706 in FIG. 7) and an EIS system test database (e.g., test database 708 in FIG. 7) respectively. The EIS system battery fail module may perform EIS tests based on the downloaded data. The data may include commands, which may be specific instructions for an EIS tester (e.g., battery tester circuit 716 in FIG. 7) for the manner the test may be conducted. For example, a command may be “Apply input for 2 sec. and take output for 3 sec.” Input attributes, or EIS test waveform parameters, may not defined in the command. The EIS test waveform parameters may be obtained from the EIS system test database, which may contain EIS test waveform parameters, such as frequency, amplitude, or power density of a waveform to be generated.

The EISA network battery module may also constantly poll all the batteries (e.g., battery 742 in FIG. 7) in its network to check whether the batteries are doing well. A plurality of EIS systems may be continuously performing tests on batteries and the EIS systems may upload the EIS test data along with battery performance data to the EISA network learned database. In response to an upload request received by the EISA network battery module, the EISA network battery module may pull data (data for the EIS system test database) for the batteries into the EISA network learned database and learn about the patterns of the batteries. For instance, the EISA network battery module may detect a group of batteries from a large number of similar batteries that may start to perform poorly. The EISA network battery module may identify a battery type and an adverse performance event, and determine if there is a correlation with historical data for similar performance events that have been stored with respect to other batteries of similar type. Based on the analysis, the EISA network battery module may correlate certain EIS tests and certain responses indicative of a specific performance issue, such as overheating, undercharging etc. The EISA network battery module may update correlation coefficients with respect to new performance events reported by the EIS system. Further, in response to the correlation coefficient exceeding a predetermined threshold (i.e. 90%), the EISA network battery module may suggest conducting more EIS tests on the concerned batteries. These additional tests may be conducted during idle periods, such as nights, or any other specific period. Thus, based on a large number of crowd sourced EIS test data, a reliable test may be confirmed that is indicative of a specific problem associated with a battery that risks it safe operation. These tests may be downloaded to all the EIS systems (to the test database and the command database) associated with the battery type so that they can detect such problems earlier and resolve the same.

The method 1000 may be implemented in software executing in a software-configurable processor of a server of the EISA network. In order to encompass the alternative configurations enabled in various embodiments, the hardware implementing the method 1000 is referred to herein as an “EISA network server.”

In block 1002, the EISA network server may poll for a request from an EIS system. A request from the EIS system may include any combination of battery identifying information, charger identifying information, EIS testing information (such as EIS test waveform parameter data and EIS testing commands), a request for download of the information on the battery to trigger transmission of the information on the battery from an EISA network learned database, and/or a request for upload of information from the EIS system to trigger transmission of information on the battery to the EISA network server. The EISA network learned database may be stored on a persistent or volatile memory of the EISA network server. The information on the battery may include any combination and/or association of battery identifying information, battery charging information for the battery, and/or EIS testing information for the battery. The EISA network server may check a communication interface, such as communication port of the server, for a request from an EIS system.

In determination block 1004, the EISA network server may determine whether there is a request to download data and commands. In response to polling for a request, the EISA network server may identify a request for download from the EIS system. The EISA network learned database may contain EIS testing information for the battery, including data for an EIS system test database and commands for an EIS command database. The request for download may trigger and/or specify downloading of any combination of the data and commands of the EIS system learned database. The request for download may be limited to data and commands for a battery connected to the EIS system.

In response to determining that the there is a request to download data and commands (i.e., determination block 1004=“Yes”), the EISA network server may extract data and commands from the EISA network learned database and send the data and commands to the EISA system battery fail module in block 1006. The request may include battery identifying information and the EISA network server may request from the EISA learned database the data and commands associated with the battery identifying information of the request. The EISA network server may return the extracted data and commands to the requesting EIS system in response to the request for download.

In response to determining that the there is not a request to download data and commands (i.e., determination block 1004=“No”); or following extracting data and commands from the EISA network learned database and sending the data and commands to the EISA system battery fail module in block 1006, the EISA network server may determine whether there is a request for upload in determination block 1008. In response to polling for a request, the EISA network server may identify a request for upload from the EIS system. The request for upload may trigger and/or specify uploading of any combination of the data of the EIS system test database, including response waveform data, battery performance parameters, and/or any combination of information for indentifying entries in the ESIA network learned database, including battery identifying information, charger identifying information, EIS testing commands, and/or EIS test waveform parameters.

In response to determining that there is a request for upload (i.e., determination block 1008=“Yes”), the EISA network server may receive data of the EISA system test database from the battery fail module and store the received data in the EISA network learned database in block 1010. The EISA network server may use any of the information for indentifying entries in the ESIA network learned database received as part of the request for upload to determine where in the EISA network learned database to store the received data of the EIS system test database. The information for indentifying entries in the ESIA network learned database may be used to identify entries and/or create entries in the ESIA network learned database for storing the data of the EIS system test database. The data of the EIS system test database may be stored to the EISA network learned database in a manner that associates the data of the EIS system test database and the information for indentifying entries in the ESIA network learned database.

In determination block 1012, the EISA network server may determine whether performance data indicates poor performance or an undesirable battery state. Over time, the ESIA network learned database may gather historical data on the performance of a variety of batteries, including multiple, similar batteries. The EISA network server may identify patterns in the historical data that may deviate from the majority of performance parameters and may correlate with (i.e., provide an indicator of) poor performance/an undesirable battery state. The uploaded performance parameters may be compared to patterns that have been correlated with poor performance/an undesirable battery state.

In response to determining that performance data indicates poor performance/an undesirable battery state (i.e., determination block 1012=“Yes”), the EISA network server may identify a battery type and a performance event in block 1014. Battery identifying information, including battery type may be provided to the EISA network server with the request for upload, and the EISA network server may extract the battery type from the data uploaded to the EISA network server. The performance parameters may also be provided to the EISA network server with the request for upload, and, the EISA network server may compare the performance parameters to historical performance parameters for performance events associated with the battery type. The EISA network server may retrieve the performance events and their performance parameters from the EISA network learned database using any combination of the uploaded data.

In block 1016, the EISA network server may calculate a correlation coefficient for the poor performance event based on historical data of the EIS system database data stored in EISA network learned database for the battery type. The EISA network server may compare the uploaded EIS test inputs and outputs to historical EIS test inputs and outputs associated with the performance event. From the comparison, the EISA network server may calculate a correlation coefficient between the uploaded EIS test inputs and outputs and the historical EIS test inputs and outputs associated with the performance event. Correlation may indicate a degree of matching between the uploaded EIS test inputs and outputs and the historical EIS test inputs and outputs associated with the performance event.

In block 1018, the EISA network server may update the correlation coefficient in the EISA network learned database for the uploaded data. The EISA network server may store the calculated correlation coefficient in the EISA network learned database in a manner that associates the correlation coefficient with the uploaded data,

In determination block 1020, the EISA network server may determine whether the correlation coefficient exceeds a threshold. The threshold may be a general or a performance event specific, predetermine or learned threshold. The EISA network server may compare the correlation coefficient with the threshold to determine whether the correlation coefficient exceeds the threshold.

In response to determining that the correlation coefficient exceeds the threshold (i.e., determination block 1020=“Yes”), the EISA network server may send data regarding further EIS test waveforms and EIS test commands strongly correlated with the poor performance event and the battery type to the EIS system battery fail module from the EISA network learned database in block 1022. The EISA network server may retrieve from the EISA network learned database, EIS test waveforms and EIS test commands associated with the battery type, performance event, and correlation coefficients that exceed the threshold.

In response to determining that there is not a request for upload (i.e., determination block 1008=“No”); in response to determining that performance data does not indicate poor performance/an undesirable battery state (i.e., determination block 1012=“No”); or in response to determining that the correlation coefficient does not exceed the threshold (i.e., determination block 1020=“No”), the EISA network server may poll for a request from an EIS system in block 1002.

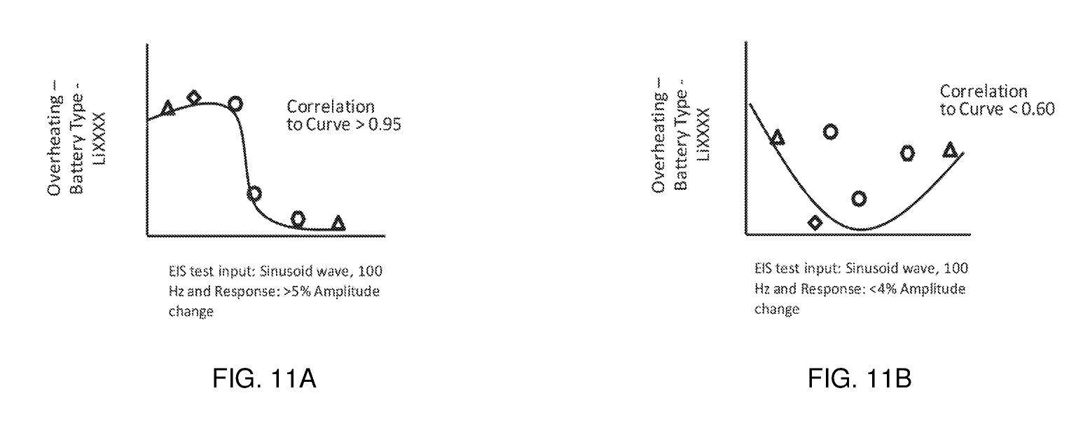

FIG. 11A illustrates EIS test input and EIS test response data, such as the EIS test waveform parameters and the digitized response waveform data, that may be well correlated to a negative performance event (e.g., overheating). The plotted points of the EIS test input and EIS test response data may closely follow a trend line of historical EIS test input and EIS test response data associated with the negative performance event. A degree of closeness of the plotted points of the EIS test input and EIS test response data following the trend line of the historical EIS test input and EIS test response data associated with the negative performance event may be indicated by a correlation coefficient. In the example illustrated in FIG. 11A, close correlation of the plotted points of the EIS test input and EIS test response data following the trend line of the historical EIS test input and EIS test response data associated with the negative performance event may be indicated by a correlation coefficient greater than 0.95.

FIG. 11B illustrates EIS test input and EIS test response data that are poorly correlated to a negative performance event (e.g., overheating). In the illustrated example, the plotted points of the EIS test input and EIS test response data do not closely follow a trend line of historical EIS test input and EIS test response data associated with the negative performance event. In the example illustrated in FIG. 11B, a lack of correlation of the plotted points of the EIS test input and EIS test response data following the trend line of the historical EIS test input and EIS test response data associated with the negative performance event may be indicated by a correlation coefficient less than 0.60.

Close correlation to a negative performance event for EIS test attributes observed in real-time, as in the example in FIG. 11A, may indicate that an action should be taken to return battery performance to a preferable or desirable state. Little to no correlation to a negative performance event for EIS test attributes observed in real-time, as in the example in FIG. 11B, may indicate that no action needs to be taken to improve battery performance.

FIG. 12 illustrates a method 1200 for managing charging of a battery using EIS testing results according to an embodiment. A charger control module (e.g., charger control module 732 in FIG. 7) may poll for a request for charging from an EIS system battery fail module (e.g., battery fail module 712 in FIG. 7). The EIS system battery fail module may decide, based on EIS tests and a battery protection algorithm, whether charging is needed and whether any special charging pattern needs to be suggested to the charger control module. The charger control module, based on the received and stored charging parameters, may instruct a charger controller (e.g., controller 736 in FIG. 7) to implement the charging pattern suggested by the EIS system battery fail module. The charger control module may continue or repeat polling for further instructions from the EIS system battery fail module. Charging instructions may include alternating patterns of ON/OFF signals (e.g., On/Off 748 in FIG. 7) or complex patterns with regards to instructions specific to a state-of-charge and charge current.

The method 1200 may be implemented in software executing in a software-configurable processor (such as a central processing unit, graphics processing unit, etc.), in general purpose hardware, in dedicated hardware, or in a combination of a software-configured processor and dedicated hardware, such as a processor executing software within a system for EIS testing (e.g., system 700A, 700B, 700C, charger 730 in FIG. 7), and various memory/cache controllers. In order to encompass the alternative configurations enabled in various embodiments, the hardware implementing the method 1200 is referred to herein as a “control device.”

In block 1202, the control device may poll for a request from an EIS system battery fail module. The control device may continuously or periodically check for requests for charging from the EIS system battery fail module. The control device may prompt the EIS system battery fail module to send any pending requests of the EIS system battery fail module.

In block 1204, the control device may receive a response from the EIS system battery fail module. The response may include the polled for request, which may include a charging suggestion for the battery. The charging suggestion may include charging instructions and/or parameters or a pattern for charging the battery. The charging instructions may include instructions not to charge the battery.

In determination block 1206, the control device may determine whether the response from the EIS system battery fail module suggests charging the battery. The control device may read and interpret signals of the response to determine whether the signals indicate a suggestion to charge the battery.

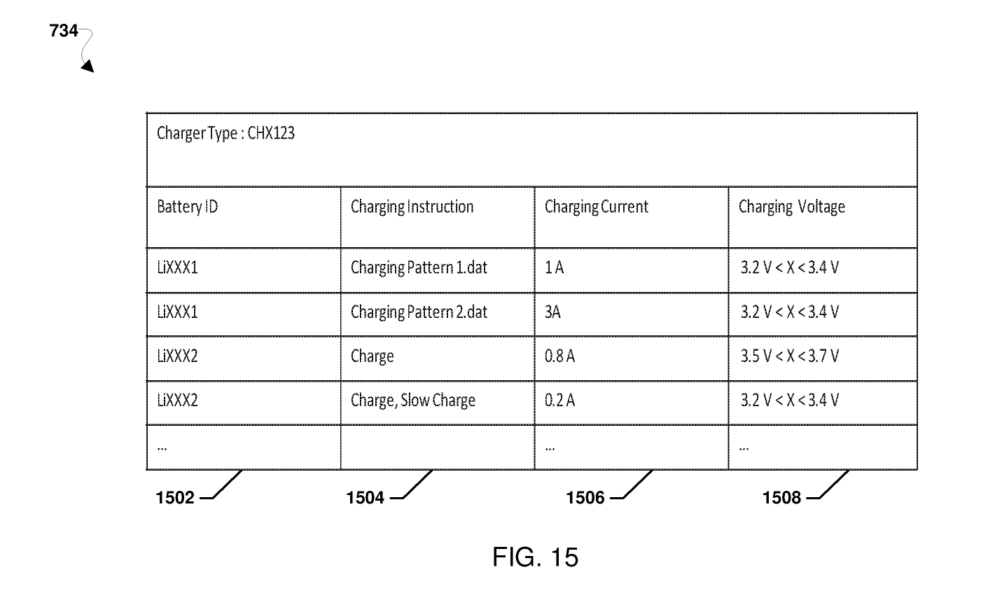

In response to determining that the response from the EIS system battery fail module suggests charging the battery (i.e., determination block 1206 =“Yes”), the control device may extract charger database (e.g., charger database 734 in FIG. 7) data and response data from the EIS system battery fail module in block 1208. The charger database may contain data relevant to charging the battery. The charger database is further described herein with reference to FIG. 15. The control device may extract data relevant to charging the battery from the charger database. The control device may also extract data relevant to charging the battery from the response from the EIS system battery fail module, such as the instruction to charge the battery and any patterns or parameters for charging the battery.

In block 1210, the control device may send charging commands to a charger controller for charging the battery. The control device may send the data extracted from the charger database and the response from the EIS system battery fail module to the charger controller. The charging commands may indicate to the charger controller to charge the battery and how to charge the battery.

In block 1212, the control device may wait for a time “X”. The time “X” may be any amount of time.

In determination block 1214, the control device may check whether charging is being implemented. The control device may check a status of the charger controller to determine whether the charger controller is charging the battery. For example, the control device may receive a signal from the charger controller while it is charging, may check a status flag of the charger controller to determine whether it is set to charging, and/or may detect a current output from the charger controller to the battery. Similarly, the control device may recognize lack of a signal or current output from the charger controller, and/or interpret a flag status to indicate that the charger controller is not charging the battery. In response to interpreting that the charger controller is not charging the battery, the control device may determine that the charging instructions have been completed.

In response to determining that charging is being implemented (i.e., determination block 1214=“Yes”), the control device may wait for the time “X” in block 1212.

In response to determining that the charging is not being implemented (i.e., determination block 1214=“No”); or in response to determining that the response from the EIS system battery fail module does not suggest charging the battery (i.e., determination block 1206=“No”), the control device may poll for a request from an EIS system battery fail module in block 1202.

FIG. 13 illustrates an example battery protection algorithm decision matrix 1300 which may be stored to volatile and/or persistent memory of an EIS system (e.g., EIS system 702 in FIG. 7), and may be stored as part of a battery protection algorithm. The battery protection algorithm decision matrix 1300 may represent various operable test patterns that have been learnt by an EISA network learned database (e.g., learned database 724 in FIG. 7) that may indicate preferred and non-preferred states of batteries (e.g., battery 742 in FIG. 7). A preferred operating state may not require any charging or may require normal charging. An abnormal state may require special parameters or pattern for charging the batteries. In response to not being able to avert a non-preferred state of a battery through an action by a charger control module (e.g., charger control module 732 in FIG. 7), a user might also be advised to lower his usage of a device (e.g., battery-powered device 744 in FIG. 7) to limit any damage to the battery or the device. However, in response to a problem persisting and rising to an alarm level, as may be detected in terms of a response by an EIS system (e.g., EIS system 702 in FIG. 7), halting instruction might be sent to the battery-powered device. In response to the user not responding to such a high priority recommendation, the device may be automatically put in a power-down state to avoid harm to the battery.

Column 1 1302 may store a test identifier. Column 2 1304 may store test waveforms that may be used for specific battery types. For example, the EIS test waveforms may be different types of waveforms (e.g., sinusoidal wave, 100Hz, and sinusoidal wave, 200Hz) applied as input to the battery. Reflected/response waveforms may result from application of the EIS test waveforms to the battery. A comparison of an input EIS test waveform and a reflected waveform may be represented as a number or score as a percentage of a difference between the input EIS test waveform and reflected waveform to the input EIS test waveform. The difference may be in the form of frequency difference, amplitude difference, etc. Based on the score, a decision regarding charging and charging parameters, stored in column 5 1310, may be made. To determine the decision in column 5 1310, the score, depending on its format, may be compared to predefined and/or learned ranges stored in column 3 1306 and/or column 4 1308. A score formatted in terms of amplitude may compared to the ranges stored in column 3 1306, and a score formatted in terms of frequency may be compared to ranges stored in column 4 1308. By such comparisons the response may be matched to a pattern of known responses (which may be represented in the ranges in column 3 1306 and/or column 4 1308) that indicates a problem or no problem with batteries. Some EIS tests may be useful in finding non-severe, minor problems that can be corrected by charging the battery using specific charging patterns, such as alternating between ON/OFF states of charging. Such patterns may help in solving battery problems, like holding a shorter charge, overheating, etc. Other problems, as indicated by the EIS tests, may require user intervention or, in extreme cases, complete shut-down, like while avoiding fire hazards.

FIG. 14 illustrate an example learned database 724 which may be stored to volatile and/or persistent memory of an EISA network (e.g., EISA network 720 in FIG. 7). The learned database 724 may contain learning from historical data related to EIS tests conducted on various types of batteries (e.g., battery 742 in FIG. 7). Data may be collected primarily through an EIS system communication module (e.g., comms module 704 in FIG. 7). The EIS system communication module may upload EIS test results related to the batteries, to which an EIS system (e.g., EIS system 702 in FIG. 7) may be connected, along with performance parameters of the batteries. The learned database 724 may analyze the EIS test data and EIS test response data against the performance parameters and prescribe those tests and response range value for EIS tests that may characterize poor performance.

Column one 1402 may store a battery type and column two 1404 may store a battery identifier, as EIS tests may be applicable to variety of battery technologies and models. Column three 1406 may store EIS test waveform parameters found to be most suitable for testing the performance of respective batteries. Column four 1408 may store commands for the EIS system to apply the EIS test parameters stored in column three 1406 and collect EIS test response data from the EIS system. Column five 1410 may store a range of response waveforms with respect to an input EIS test waveform that may be considered to be indicative of poor performance. Variation of EIS test response data outside this allowed range may indicate a requirement for countermeasures to bring the battery state back within a preferred operating range. Column six 1412 may store a charger type that may be associated with the charging of the battery. Column seven 1414 may store a preferred operating charging current and column eight 1416 may store a preferred operating charging voltage that may be employed by a charger (e.g., charger 730 in FIG. 7) of the type identified in column six 1412 for charging the respective battery. Column nine 1418 may store performance parameters of a battery/device (e.g., battery-powered device 744 in FIG, 7) that may be received either with the EIS test results or separately. The performance data may include temperature, voltage, current, or any other parameter that indicates a problem with the battery. Column ten 1420 may store a correlation coefficient between a performance event and the EIS test represented by the EIS test waveform, an EIS test command, and the response range.

FIG.15 illustrates an example charger database 734 located on a volatile and/or persistent memory of a charger (e.g., charger 730 in FIG. 7). Column one 1502 may store different types of batteries (e.g., battery 742 in FIG. 7) supported by the charger. The charger may be a built-in smart charger that may charge various kinds of batteries and devices (e.g., battery-powered device 744 in FIG. 7). For example, the same charger may be utilized for a laptop that supports both 6-cell and 9-cell batteries. Column two 1504 may store charging instruction that the charger may receive from an EIS system (e.g., EIS system 702). Column three 1506 and column four 1508 may store specific charging parameters, such as a charging current and a charging voltage, that may be used for charging a battery in response to receiving respective charging instructions.

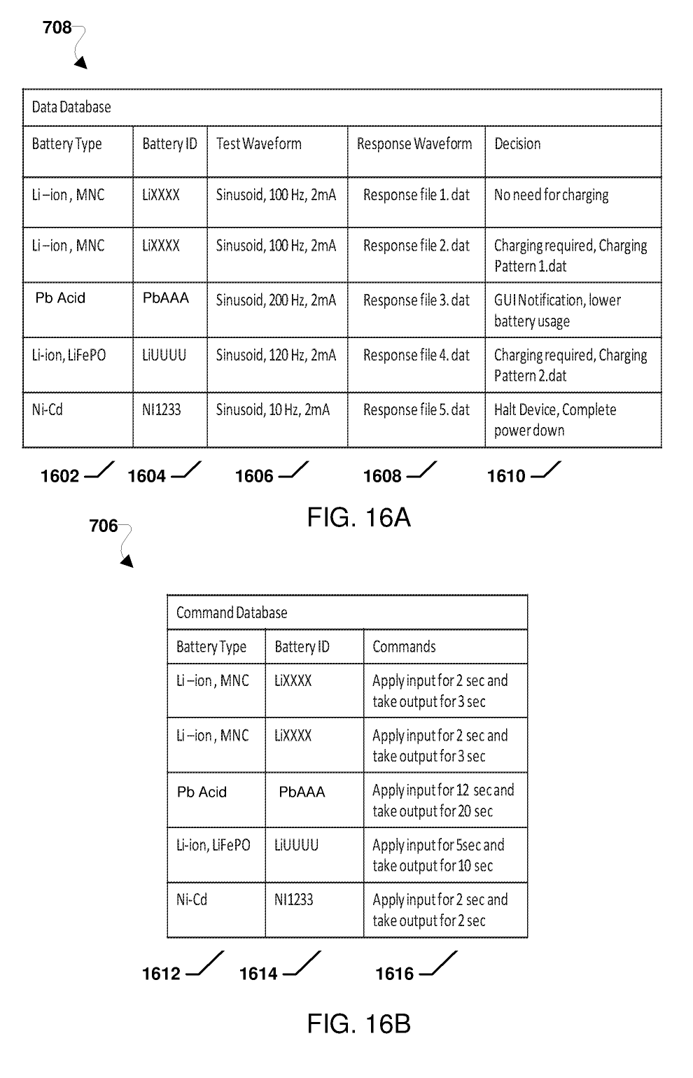

FIGS. 16A and 16B illustrate an example test database 708 and command database 706, respectively. The test database and the command database may be located on any combination of volatile and/or persistent memories of an EIS system (e.g., EIS system 702 in FIG. 7). These databases 706, 708 may contain portions of information stored in an EISA network learned database (e.g., learned database 724 in FIG. 7).

The test database 708 may store EIS test waveform data for performing EIS tests on batteries (e.g., battery 742 in FIG. 7) connected to the EIS system to test the battery state and to keep it within normal operating levels to prevent hazardous events. Column one 1602 may store a battery type and column two 1604 may store a battery identifier. Column three 1606 may store EIS test parameters that may be downloaded by a communication module (e.g., comms. module 704 in FIG. 7) of the EIS system from the learned database via an EISA network battery module (e.g., battery module 722 in FIG. 7). Column four 1608 may store an output or response waveform in a digital data file format that may be generated by passing the output waveform obtained from an EIS tester (e.g., battery tester circuit 716 in FIG. 7) through an analog-to-digital converter (e.g., analog-to-digital converter 714 in FIG. 7). Column five 1610 may store a decision made by the EIS system based on implementation of a battery protection algorithm, which may be stored as a portion of code/software within the microprocessor (e.g., microprocessor 710 in FIG. 7) and/or on volatile and/or persistent memory of the EIS system.

The command database 706 may store EIS instructions that may be sent to the tester for conducting the EIS test. Column one 1612 and column two 1614 may store a battery type and a battery identifier. Column three 1616 may store EIS test commands, such as when and for how long test signals may be applied to the battery, and when and how long output signal from the battery may be measured. There may be other forms of instructions possible that may be stored in the command database 706.

The EISA system test database 708 and the EISA network 720 may be implemented on any of a variety of commercially available computing devices, such as a server 1700 as illustrated in FIG. 17. Such a server 1700 typically includes a processor 1701 coupled to volatile memory 1702 and a large capacity nonvolatile memory, such as a disk drive 1703. The server 1700 may also include a floppy disc drive, compact disc (CD) or DVD disc drive 1704 coupled to the processor 1701. The server 1700 may also include network access ports 1706 coupled to the processor 1701 for establishing data connections with a network 1705, such as a local area network coupled to other operator network computers and servers.

With reference to FIGS. 1-17, some embodiments include methods for electrochemical impedance spectroscopy (EIS) analysis of a battery that include performing an EIS test on a battery, identifying a battery condition based on the analysis of EIS test results, and implementing a battery protection action responsive to the identified battery condition.

In some embodiments, performing an EIS test on the battery, identifying a battery condition based on the analysis of EIS test results, and implementing a battery protection action responsive to the identified battery condition may be performed by a battery fail module (712) coupled to the battery.

In some embodiments, performing an EIS test on a battery includes applying a test waveform to the battery, determining a response waveform of the battery, and determining an impedance response of the battery at a frequency of the test waveform based on a comparison of the response waveform to the applied test waveform. In such embodiments, identifying a battery condition based on the analysis of EIS test results comprises determining the battery condition based on the impedance response of the battery at the frequency of the test waveform.

In some embodiments, performing an EIS test on a battery includes applying a plurality of different test waveforms to the battery, determining a response waveform of the battery for each of the plurality of different test waveforms, and determining an impedance response of the battery for each of the plurality of different test waveforms based on a comparison of each response waveform to each applied test waveform. In such embodiments, identifying a battery condition based on the analysis of EIS test results comprises determining the battery condition based on the impedance response of the battery for each of the plurality of different test waveforms.

In some embodiments, performing an EIS test on a battery includes applying a test waveform to the battery, and determining a response waveform of the battery. In such embodiments, identifying a battery condition based on the analysis of EIS test results comprises comparing the EIS test waveform and the response waveform and determining a score based on the comparison of the EIS test waveform and the response waveform, and implementing a battery protection action responsive to the identified battery condition comprises determining the battery protection action from an entry in a battery protection decision matrix corresponding to the determined score, and executing the determined battery protection action.

In some embodiments, implementing a battery protection action responsive to the identified battery condition comprises performing one or more of charging the battery, generating a notification on a graphical user interface, powering down a device coupled to the battery, or disconnecting the battery from a device.

In some embodiments, performing an EIS test on a battery comprises applying a first test waveform to the battery and determining a first response waveform of the battery. Such embodiments may further include uploading the first response waveform to a server, receiving parameters for a second test waveform from the server, applying the second test waveform to the battery, and determining a second response waveform of the battery. In such embodiments, identifying a battery condition based on the analysis of EIS test results comprises identifying the battery condition based on comparisons of the first response waveform to the first test waveform and of the second response waveforms to the second test waveform.

With reference to FIGS. 1-17, some embodiments include an electrochemical impedance spectroscopy (EIS) device (702) for use on a battery powered device, comprising a battery tester circuit (716) configured to performing an EIS test on a battery (742), and a control device (e.g., 138, 710) coupled to the battery tester and configured to perform operations comprising: performing an EIS test on the battery, identifying a battery condition based on the analysis of EIS test results; and implementing a battery protection action responsive to the identified battery condition. In some embodiments, the control device comprises a processor (710) within or coupled to a battery fail module (712) coupled to the battery tester circuit (716). In some embodiments, the battery tester circuit (716) includes a test waveform generator (717) configured to generate a test waveform in response to parameters provided by the control device, and a response waveform detector (718) configured to measure at least one of voltage or current across the battery at a sampling interval to determine a response waveform.

In some embodiments, the control device is further configured to perform operations such that performing an EIS test on a battery comprises determining an impedance response of the battery at a frequency of the test waveform based on a comparison of the response waveform to the applied test waveform, and identifying a battery condition based on the analysis of EIS test results comprises determining the battery condition based on the impedance response of the battery at the frequency of the test waveform.

In some embodiments, the control device is further configured to perform operations such that performing an EIS test on a battery comprises determining an impedance response of the battery for each of a plurality of different test waveforms based on a comparison of each response waveform to each applied test waveform, and identifying a battery condition based on the analysis of EIS test results comprises determining the battery condition based on the impedance response of the battery for each of the plurality of different test waveforms.

In some embodiments, the control device is further configured to perform operations such that identifying a battery condition based on the analysis of EIS test results comprises comparing the EIS test waveform and the response waveform and determining a score based on the comparison of the EIS test waveform and the response waveform, and implementing a battery protection action responsive to the identified battery condition includes determining the battery protection action from an entry in a battery protection decision matrix corresponding to the determined score, and executing the determined battery protection action.

In some embodiments, the control device is further configured to perform operations such that implementing a battery protection action responsive to the identified battery condition comprises performing one or more of signaling a battery charger to charge the battery, generating a notification on a graphical user interface, signaling the battery powered device to power down, or opening a switch to disconnect the battery from the battery powered device.

In some embodiments, the control device is further configured to perform operations such that performing an EIS test on a battery includes applying a first test waveform to the battery, and determining a first response waveform of the battery. In such embodiments, the control device is configured to perform operations further comprising uploading the first response waveform to an electrochemical impedance spectroscopy analyzer (EISA) server (720, 1700); receiving parameters for a second test waveform from the EISA server; applying the second test waveform to the battery, and determining a second response waveform of the battery. In such embodiments, the control device may be further configured to perform operations such that identifying a battery condition based on the analysis of EIS test results comprises identifying the battery condition based on comparisons of the first response waveform to the first test waveform and of the second response waveforms to the second test waveform.

With reference to FIGS. 1-17, some embodiments include electrochemical impedance spectroscopy analyzer (EISA) system, comprising: an EISA network server (720, 1700), comprising a battery module (722), and a learned database (724), wherein the battery module is configured to receive an EIS test waveform for an electrochemical impedance spectroscopy (EIS) test on a battery, a response waveform for the EIS test, and performance parameters of the battery from an EIS system (702), and store the EIS test waveform, the response waveform, and the performance parameters in the learned database as associated with the battery, and wherein the learned database is configured to compare the EIS test waveform, the response waveform, and the performance parameters with historical EIS test waveforms, historical response waveforms, and historical performance parameters associated with a type of battery corresponding to the type of battery for the battery and a poor performance event for the battery to determine EIS testing information for the battery exhibiting the poor performance event. In some embodiments, the learned database is further configured to identify patterns in the historical performance parameters associated with the type of battery that indicate the poor performance event.

In some embodiments, the learned database is configured such that comparing the EIS test waveform, the response waveform, and the performance parameters with historical EIS test waveforms, historical response waveforms, and historical performance parameters comprises calculating a correlation between the EIS test waveform, the response waveform, and the performance parameters and the historical EIS test waveforms, the historical response waveforms, and the historical performance parameters. In such embodiments, the learned database is further configured to determine whether the calculated correlation exceeds a threshold, and provide a further EIS test waveform and further EIS test commands associated with the poor performance event in response to determining that the calculated correlation exceeds the threshold. In such embodiments, the learned database may be further configured to update an entry associating the battery type and the poor performance event to include the calculated correlation.

In some embodiments, the battery module is configured to determine whether there is a request to upload from the EIS system, wherein receiving an EIS test waveform for an EIS test on a battery, a response waveform for the EIS test, and performance parameters of the battery, storing the EIS test waveform, the response waveform, and the performance parameters in the learned database as associated with the battery, and comparing the EIS test waveform, the response waveform, and the performance parameters with historical EIS test waveforms, historical response waveforms, and historical performance parameters occur in response to determining that there is a request to upload from the EIS system, and sending the further EIS test waveform and the further EIS test commands to the EIS system.

With reference to FIGS. 1-17, some embodiments include a method for managing sharing of electrochemical impedance spectroscopy (EIS) battery testing data, comprising: receiving an EIS test waveform for an EIS test on a battery, a response waveform for the EIS test, and performance parameters of the battery from an EIS system; storing the EIS test waveform, the response waveform, and the performance parameters in a learned database in a manner associated with the battery; and comparing the EIS test waveform, the response waveform, and the performance parameters with historical EIS test waveforms, historical response waveforms, and historical performance parameters associated with a type of battery corresponding to the type of battery for the battery and a poor performance event for the battery to determine EIS testing information for the battery exhibiting the poor performance event. Some embodiments may further include identifying patterns in the historical performance parameters associated with the type of battery that correlate with poor performance events.

In some embodiments, analyzing the EIS test waveform, the response waveform, and the performance parameters with historical EIS test waveforms, historical response waveforms, and historical performance parameters comprises calculating a correlation between the EIS test waveform, the response waveform, and the performance parameters and the historical EIS test waveforms, the historical response waveforms, and the historical performance parameters. Such embodiments may further include determining whether the calculated correlation exceeds a threshold, and providing a further EIS test waveform and further EIS test commands associated with the poor performance event in response to determining that the calculated correlation exceeds the threshold. Such embodiments may further include updating an entry associating the battery type and the poor performance event to include the calculated correlation. Such embodiments may further include determining whether there is a request to upload from the EIS system, wherein receiving an EIS test waveform for an EIS test on a battery, a response waveform for the EIS test, and performance parameters of the battery, storing the EIS test waveform, the response waveform, and the performance parameters in a learned database as associated with the battery, and analyzing the EIS test waveform, the response waveform, and the performance parameters with historical EIS test waveforms, historical response waveforms, and historical performance parameters occur in response to determining that there is a request to upload from the EIS system, and sending the further EIS test waveform and the further EIS test commands to the EIS system.

The processors may be any programmable microprocessor, microcomputer or multiple processor chip or chips that can be configured by software instructions (applications) to perform a variety of functions, including the functions of the various embodiments described in this application. In some wireless devices, multiple processors may be provided, such as one processor dedicated to wireless communication functions and one processor dedicated to running other applications. Typically, software applications may be stored in the internal memory 1703 before they are accessed and loaded into the processor. The processor may include internal memory sufficient to store the application software instructions.

The foregoing method descriptions and diagrams are provided merely as illustrative examples and are not intended to require or imply that the steps of the various embodiments must be performed in the order presented. As will be appreciated by one of skill in the art the order of steps in the foregoing embodiments may be performed in any order. Further, words such as “thereafter,” “then,” “next,” etc. are not intended to limit the order of the steps; these words are simply used to guide the reader through the description of the methods.

One or more diagrams have been used to describe exemplary embodiments. The use of diagrams is not meant to be limiting with respect to the order of operations performed. The foregoing description of exemplary embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

Control elements may be implemented using computing devices (such as computer) comprising processors, memory and other components that have been programmed with instructions to perform specific functions or may be implemented in processors designed to perform the specified functions. A processor may be any programmable microprocessor, microcomputer or multiple processor chip or chips that can be configured by software instructions (applications) to perform a variety of functions, including the functions of the various embodiments described herein. In some computing devices, multiple processors may be provided. Typically, software applications may be stored in the internal memory before they are accessed and loaded into the processor. In some computing devices, the processor may include internal memory sufficient to store the application software instructions.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The hardware used to implement the various illustrative logics, logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Alternatively, some blocks or methods may be performed by circuitry that is specific to a given function.

The preceding description of the disclosed embodiments is provided to enable any person skilled in the art to make or use the described embodiment. Various modifications to these embodiments will be readily apparent to those skilled in the art, and the generic principles defined herein may be applied to other embodiments without departing from the scope of the disclosure. Thus, the present invention is not intended to be limited to the embodiments shown herein but is to be accorded the widest scope consistent with the following claims and the principles and novel features disclosed herein.

1. A method for electrochemical impedance spectroscopy (EIS) analysis of a battery, comprising:
performing an EIS test on a battery;
identifying a battery condition based on analysis of EIS test results; and
implementing a battery protection action responsive to the identified battery condition.

2. The method of claim 1, wherein performing an EIS test on the battery, identifying a battery condition based on the analysis of EIS test results, and implementing a battery protection action responsive to the identified battery condition are performed by a battery fail module coupled to the battery.

3. The method of claim 1, wherein:
performing an EIS test on a battery comprises:
applying a test waveform to the battery;
determining a response waveform of the battery; and
determining an impedance response of the battery at a frequency of the test waveform based on a comparison of the response waveform to the applied test waveform; and
identifying a battery condition based on the analysis of EIS test results comprises determining the battery condition based on the impedance response of the battery at the frequency of the test waveform.

4. The method of claim 1, wherein:
performing an EIS test on a battery comprises:
applying a plurality of different test waveforms to the battery;
determining a response waveform of the battery for each of the plurality of different test waveforms; and
determining an impedance response of the battery for each of the plurality of different test waveforms based on a comparison of each response waveform to each applied test waveform; and
identifying a battery condition based on the analysis of EIS test results comprises determining the battery condition based on the impedance response of the battery for each of the plurality of different test waveforms.

5. The method of claim 1, wherein:
performing an EIS test on a battery comprises:
applying a test waveform to the battery; and
determining a response waveform of the battery; and
identifying a battery condition based on the analysis of EIS test results comprises comparing the test waveform and the response waveform and determining a score based on the comparison of the test waveform and the response waveform; and
implementing a battery protection action responsive to the identified battery condition comprises:
determining the battery protection action from an entry in a battery protection decision matrix corresponding to the determined score; and
executing the determined battery protection action.

6. The method of claim 1, wherein implementing a battery protection action responsive to the identified battery condition comprises performing one or more of charging the battery, generating a notification on a graphical user interface, powering down a device coupled to the battery, or disconnecting the battery from a device.

7. The method of claim 1, wherein performing an EIS test on a battery comprises applying a first test waveform to the battery and determining a first response waveform of the battery, the method further comprising:
uploading the first response waveform to a server;
receiving parameters for a second test waveform from the server;
applying the second test waveform to the battery; and
determining a second response waveform of the battery,
wherein identifying a battery condition based on the analysis of EIS test results comprises identifying the battery condition based on comparisons of the first response waveform to the first test waveform and of the second response waveforms to the second test waveform.

8. A electrochemical impedance spectroscopy (EIS) device for use on a battery powered device, comprising:
a battery tester circuit configured to performing an EIS test on a battery; and
a control device coupled to the battery tester and configured to perform operations comprising:
performing an EIS test on the battery;
identifying a battery condition based on analysis of EIS test results; and
implementing a battery protection action responsive to the identified battery condition.

9. The EIS device of claim 8, wherein the control device comprises a processor within a battery fail module coupled to the battery tester circuit.

10. The EIS device of claim 8, wherein the battery tester circuit comprises:
a test waveform generator configured to generate a test waveform in response to parameters provided by the control device; and
a response waveform detector configured to measure at least one of voltage or current across the battery at a sampling interval to determine a response waveform.

11. The EIS device of claim 10, wherein the control device is further configured to perform operations such that:
performing an EIS test on a battery comprises determining an impedance response of the battery at a frequency of the test waveform based on a comparison of the response waveform to the applied test waveform; and
identifying a battery condition based on the analysis of EIS test results comprises determining the battery condition based on the impedance response of the battery at the frequency of the test waveform.

12. The EIS device of claim 10, wherein the control device is further configured to perform operations such that:
performing an EIS test on a battery comprises determining an impedance response of the battery for each of a plurality of different test waveforms based on a comparison of each response waveform to each applied test waveform; and
identifying a battery condition based on the analysis of EIS test results comprises determining the battery condition based on the impedance response of the battery for each of the plurality of different test waveforms.

13. The EIS device of claim 10, wherein the control device is further configured to perform operations such that:
identifying a battery condition based on the analysis of EIS test results comprises comparing the test waveform and the response waveform and determining a score based on the comparison of the test waveform and the response waveform; and
implementing a battery protection action responsive to the identified battery condition comprises:
determining the battery protection action from an entry in a battery protection decision matrix corresponding to the determined score; and
executing the determined battery protection action.

14. The EIS device of claim 10, wherein the control device is further configured to perform operations such that implementing a battery protection action responsive to the identified battery condition comprises performing one or more of signaling a battery charger to charge the battery, generating a notification on a graphical user interface, signaling the battery powered device to power down, or opening a switch to disconnect the battery from the battery powered device.

15. The EIS device of claim 10, wherein:
the control device is further configured to perform operations such that performing an EIS test on a battery comprises:
applying a first test waveform to the battery; and
determining a first response waveform of the battery; and
the control device is configured to perform operations further comprising:
uploading the first response waveform to an electrochemical impedance spectroscopy analyzer (EISA) server;
receiving parameters for a second test waveform from the EISA server;
applying the second test waveform to the battery; and
determining a second response waveform of the battery,
the control device is further configured to perform operations such that identifying a battery condition based on the analysis of EIS test results comprises identifying the battery condition based on comparisons of the first response waveform to the first test waveform and of the second response waveforms to the second test waveform.

16-20. (canceled)

21. A method for managing sharing of electrochemical impedance spectroscopy (EIS) battery testing data, comprising:
receiving an EIS test waveform for an EIS test on a battery, a response waveform for the EIS test, and performance parameters of the battery from an EIS system;
storing the EIS test waveform, the response waveform, and the performance parameters in a learned database as associated with the battery, and
comparing the EIS test waveform, the response waveform, and the performance parameters with historical EIS test waveforms, historical response waveforms, and historical performance parameters associated with a type of battery corresponding to the type of battery for the battery and a poor performance event for the battery to determine EIS testing information for the battery exhibiting the poor performance event.

22. The method of claim 21, further comprising identifying patterns in the historical performance parameters associated with the type of battery that correlate with poor performance events.

23. The method of claim 22, wherein analyzing the EIS test waveform, the response waveform, and the performance parameters with historical EIS test waveforms, historical response waveforms, and historical performance parameters comprises calculating a correlation between the EIS test waveform, the response waveform, and the performance parameters and the historical EIS test waveforms, the historical response waveforms, and the historical performance parameters, and
wherein the method further comprises:
determining whether the calculated correlation exceeds a threshold; and
providing a further EIS test waveform and further EIS test commands associated with the poor performance event in response to determining that the calculated correlation exceeds the threshold.

24. The method of claim 23, further comprising updating an entry associating battery type and the poor performance event to include the calculated correlation.

25. The method of claim 23, further comprising
determining whether there is a request to upload from the EIS system, wherein receiving an EIS test waveform for an EIS test on a battery, a response waveform for the EIS test, and performance parameters of the battery, storing the EIS test waveform, the response waveform, and the performance parameters in a learned database as associated with the battery, and analyzing the EIS test waveform, the response waveform, and the performance parameters with historical EIS test waveforms, historical response waveforms, and historical performance parameters occur in response to determining that there is a request to upload from the EIS system; and
sending the further EIS test waveform and the further EIS test commands to the EIS system.
